(19) United States
(12) Patent Application Publication
(10) Pub. No.: US 2023/0345753 A1
(43) Pub. Date: Oct. 26, 2023

(54) ELECTROLUMINESCENT DEVICE, PRODUCTION METHOD THEREOF, AND DISPLAY DEVICE INCLUDING THE SAME

(71) Applicant: SAMSUNG ELECTRONICS CO., LTD., Suwon-si (KR)

(72) Inventors: Moon Gyu HAN, Suwon-si (KR); Dae Young CHUNG, Suwon-si (KR); Taehyung KIM, Suwon-si (KR); Heejae LEE, Suwon-si (KR)

(21) Appl. No.: 18/304,714

(22) Filed: Apr. 21, 2023

(30) Foreign Application Priority Data
Apr. 22, 2022 (KR) 10-2022-0050287

(51) Int. Cl. H10K 50/13; H10K 50/16; H10K 71/15

(52) U.S. Cl. CPC H10K 50/13; H10K 50/16; H10K 71/15; H10K 2102/351

(57) ABSTRACT

An electroluminescent device including a light emitting layer disposed between a first electrode and a second electrode, and an electron transport layer disposed between the multi-layered light emitting film and the second electrode, where the multi-layered light emitting film includes a first layer and a second layer disposed on the first layer, the first layer including a plurality of first semiconductor nanoparticles surrounded by a p-type organic semiconductor polymer, and the second layer including a plurality of second semiconductor nanoparticles

### CROSS-REFERENCE TO RELATED APPLICATION

This application claims priority to Korean Patent Application No. 10-2022-0050287 filed in the Korean Intellectual Property Office on Apr. 22, 2022, and all the benefits accruing therefrom under 35 U.S.C. § 119, the entire content of which is incorporated herein by reference.

### BACKGROUND

### 1. Field

The present disclosure relates to an electroluminescent device, a production method to the electroluminescent device, and a display device including the electroluminescent device.

### 2. Description of the Related Art

A semiconductor particle of a nanoscale size (e.g., a semiconductor nanocrystal particle or a quantum dot) may exhibit luminescence. For example, a quantum dot may exhibit a quantum confinement effect. Light emission from a semiconductor nanoparticle may be generated, e.g., when electrons in an excited state transition from a conduction band to a valence band by, for example, light excitation or voltage application. A semiconductor nanoparticle may emit light in a desired wavelength region by controlling a size and/or composition of the semiconductor nanoparticle. The nanoparticle may be used in a light emitting device (e.g., an electroluminescent device) and display devices including the same.

### SUMMARY

An embodiment relates to a light emitting (e.g., electroluminescent) device including a nanoparticle (e.g., a quantum dot) that emits light by applying a voltage.

An embodiment relates to a display device (e.g., a quantum dot (QD)-light emitting diode (LED) display) including a semiconductor nanoparticle (e.g., a quantum dot) as a light emitting material present in one or more pixels of a display device.

An embodiment relates to a production method of the light emitting device.

In an embodiment, an electroluminescent device includes a first electrode; a second electrode (for example, each with a surface facing the other); and a multi-layered light emitting film, the multi-layered light emitting film disposed between the first electrode and the second electrode; and an electron transport layer disposed between the multi-layered light emitting film and the second electrode,

wherein the multi-layered light emitting film is configured to emit a first light having a predetermined peak emission wavelength,

wherein the multi-layered light emitting film includes a first layer and a second layer, the first layer including a plurality of first semiconductor nanoparticles surrounded by a p-type organic semiconductor polymer, and the second layer including a plurality of second semiconductor nanoparticles. In the second layer, at least two or more of the plurality of second semiconductor nanoparticles may be adjacent from one another. The second layer may be adjacent to the first layer.

The first semiconductor nanoparticles and the second semiconductor nanoparticles may be configured to emit the first light.

The second layer may be disposed on the first layer.

In the electroluminescent device, the second layer may be disposed between the first layer and the electron transport layer.

In the electroluminescent device, the first layer may be disposed between the second layer and the electron transport layer.

The predetermined peak emission wavelength may be in a blue wavelength range.

The blue wavelength range may be greater than or equal to about 440 nanometers (nm) or greater than or equal to about 450 nm and less than or equal to about 475 nm, or less than or equal to about 470 nm.

The predetermined peak emission wavelength may be in a green wavelength range.

The green wavelength range may be greater than or equal to about 500 nm or greater than or equal to about 515 nm and less than or equal to about 580 nm, or less than or equal to about 540 nm.

The predetermined peak emission wavelength may be in a red wavelength range.

The red wavelength range may be greater than or equal to about 600 nm or greater than or equal to about 615 nm and less than or equal to about 680 nm, or less than or equal to about 650 nm.

The first light may have a full width at half maximum (fwhm) of greater than or equal to about 5 nm, or greater than or equal to about 10 nm and less than or equal to about 50 nm, or less than or equal to about 40 nm.

The electron transport layer may include a zinc oxide nanoparticle.

In an embodiment, the zinc oxide nanoparticles may have a size or an average size (hereinafter, “a size”) of greater than or equal to about 0.5 nanometers (nm).

The zinc oxide nanoparticles may have a size of less than or equal to about 50 nm.

The zinc oxide nanoparticles may have a size of less than or equal to about 20 nm.

The zinc oxide nanoparticles may have a size of greater than or equal to about 2 nm and less than or equal to about 10 nm, greater than or equal to about 2.5 nm and less than or equal to about 7 nm, greater than or equal to about 3 nm and less than or equal to about 5 nm, or a combination thereof.

The zinc oxide nanoparticle may further include a Group IIA metal, zirconium (Zr), tungsten (W), lithium (Li), titanium (Ti), yttrium (Y), aluminum (Al), gallium (Ga), indium (In), tin (Sn), cobalt (Co), vanadium (V), or a combination thereof.

The Group IIA metal (i.e., an alkaline-earth metal) may include magnesium, calcium, beryllium, strontium, barium, or a combination thereof.

The zinc oxide nanoparticle may further include an alkali metal. The alkali metal may include cesium, potassium, rubidium, or a combination thereof.

The plurality of the first semiconductor nanoparticles may not include cadmium, lead, or both.

The plurality of the second semiconductor nanoparticles may not include cadmium, lead, or both.

The plurality of the first semiconductor nanoparticles or the plurality of the second semiconductor nanoparticles (hereinafter, simply referred to as “the plurality of the nanoparticles) may include an indium phosphide, an indium zinc phosphide, a zinc chalcogenide, or a combination thereof.

In an embodiment, the plurality of the nanoparticles may include a first semiconductor nanocrystal including zinc, selenium, and tellurium, and a second semiconductor nanocrystal including a zinc chalcogenide and being different from the first semiconductor nanocrystal.

A size or an average size (hereinafter, “size”) of the plurality of the nanoparticles may be greater than or equal to about 4 nanometers (nm), greater than or equal to about 5 nm, greater than or equal to about 7 nm, greater than or equal to about 8 nm, greater than or equal to about 9 nm, or greater than or equal to about 10 nm. The size of the plurality of semiconductor nanoparticles may be less than or equal to about 30 nm, less than or equal to about 20 nm, less than or equal to about 15 nm, less than or equal to about 12 nm, or less than or equal to about 10 nm.

The plurality of nanoparticles may have a core shell structure that includes a core including the first semiconductor nanocrystal and a shell disposed on the core and including the second semiconductor nanocrystal.

The plurality of nanoparticles may include an organic ligand and optionally a halogen, (for example being coordinated) on a surface thereof.

The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, or a combination thereof, wherein R and R′ are each independently a substituted or unsubstituted C1 to C40 aliphatic hydrocarbon, or a substituted or unsubstituted C6 to C40 aromatic hydrocarbon, or a combination thereof.

The halogen may include fluorine, chlorine, bromine, iodine, or a combination thereof.

In a multilayer light emitting film of an embodiment, a population density of the plurality of first semiconductor nanoparticles in the first layer may be less than a population density of the plurality of second semiconductor nanoparticles in the second layer. The population density can be determined with an electron microscopy analysis (e.g., a transmission electron microscopy or a scanning electron microscopy analysis) on a cross-sectional or a plane face of the multilayer light emitting film. The population density may be the number of semiconductor nanoparticles present in a given area (or per unit area).

In the multi-layered light emitting layer of an embodiment, the second layer may not include an n-type small molecule organic semiconductor.

The n-type small molecule organic semiconductor may include 1,3,5-tri(diphenylphosphoryl-phen-3-yl) benzene (TP3PO), 2,4,6-tris[3-(diphenylphosphinyl)phenyl]-1,3,5-triazine (POT2T), diphenylbis(4-(pyridine-3-yl)phenyl)silane(DPPS), 3-(4-biphenyl)-4-phenyl-5-tert-butylphenyl-1,2,4-triazole (TAZ), 4-(naphthalene-1-yl)-3,5-diphenyl-4H-1,2,4-triazole (NTAZ), 1,3,5-tris(1-phenyl-1H benzimidazole-2-yl) benzene (TPBi), 4,7-diphenyl-1,10-phenanthroline (Bphen), 1,3-bis[2-(2,2′-bipyridine-6-yl)-1,3,4-oxadiazo-5-il]benzene (Bpy-OXD), 2-(4-biphenyl)-5-(4-terbutylphenyl)-1,3,4-oxadiazole (PBD), basocuproin (BCP), 4,4′-bis(carbazole-9-yl)-2,2′-dimethylbiphenyl(CDBP), tris[3-(3-pyridyl)-mesityl] borane (3TPYMB), or a combination thereof.

In the multi-layered light emitting film of an embodiment, the second layer may not include a phenyl phosphoryl benzene compound, a diphenyl phosphinylphenyl triazine compound, or a combination thereof.

In an embodiment, the multi-layered light emitting film may have a residual thickness percentage of greater than or equal to about 10% (or greater than or equal to about 20%, greater than or equal to about 50%, or greater than or equal to about 70%) and less than or equal to about 100% (or less than or equal to about 99%, less than or equal to about 95%) with respect to a C5-18 aliphatic hydrocarbon solvent, the residual thickness percentage being defined by the following equation:

residual thickness percentage=[B/A]×100

A: initial thickness of the light emitting film or layer

B: a thickness of the light emitting film or layer after being in contact with a given solvent for a time of greater than or equal to 5 and less than or equal to 60 seconds.

In an embodiment, the residual thickness percentage of the first layer may be greater than or equal to about 80%, greater than or equal to about 82%, or greater than or equal to about 92%.

In an embodiment, the residual thickness percentage of the first layer may be about 100%.

In one embodiment, the p-type organic semiconductor polymer may include a substituted or unsubstituted alkylene group, a substituted or unsubstituted phenylene group, a substituted or unsubstituted biphenylene group, —NR—, an ether group, or a combination thereof, and R is a substituted or unsubstituted C1-C30 aliphatic hydrocarbon group, a substituted or unsubstituted C6-C60 (or C30) aromatic hydrocarbon group, a substituted or unsubstituted C3-C30 heteroaromatic hydrocarbon group, a substituted or unsubstituted C3-30 alicyclic hydrocarbon group, a substituted or unsubstituted C3-30 heteroalicyclic hydrocarbon group, or a combination thereof.

The p-type organic semiconductor polymer may have a molecular weight of greater than or equal to about 700 grams per mole (g/mole), greater than or equal to about 1000 g/mole, or greater than or equal to about 1500 g/mole.

The p-type organic semiconductor polymer may have a molecular weight of less than or equal to about 100,000 g/mole, less than or equal to about 70,000 g/mole, or less than or equal to about 50,000 g/mole.

The p-type organic semiconductor polymer may have an LUMO energy level of less than 3 eV.

A thickness of the multi-layered light emitting film may be greater than or equal to about 10 nm, greater than or equal to about 25 nm, or greater than or equal to about 30 nm.

A thickness of the multi-layered light emitting film may be less than or equal to about 150 nm, less than or equal to about 100 nm, or less than or equal to about 80 nm.

A thickness of the first layer may be greater than or equal to about 5 nm, or greater than or equal to about 15 nm.

A thickness of the first layer may be less than or equal to about 80 nm, less than or equal to about 65 nm, less than or equal to about 50 nm, or less than or equal to about 40 nm.

A thickness of the second layer may be greater than or equal to about 5 nm, or greater than or equal to about 15 nm.

A thickness of the second layer may be less than or equal to about 80 nm, less than or equal to about 65 nm, less than or equal to about 50 nm, or less than or equal to about 40 nm.

In an embodiment, the electroluminescent device may have a maximum external quantum efficiency of greater than or equal to about 10%, or greater than or equal to about 12%.

In an embodiment, the electroluminescent device may have a maximum luminance of greater than or equal to about 70,000 candela per square meter (cd/m²), or greater than or equal to about 75,000 cd/m².

In an embodiment, the electroluminescent device may have a T90 of greater than or equal to about 15 hours as operated at an initial luminance of about 650 nit.

In an embodiment, the electroluminescent device may exhibit a voltage increase of less than or equal to about 0.6 volts as operated at a luminance of about 650 nit for a predetermined hours (e.g., about 80 hours). The voltage increase may be a difference between an initial voltage and a voltage operated for the predetermined hours.

In an embodiment, a method of manufacturing the electroluminescent device may include: providing a first electrode, forming a multi-layered light emitting film on the first electrode, forming an electron transport layer on the multi-layered light emitting film, and providing a second electrode on the electron transport layer, and

the forming of the multilayer light emitting layer includes

forming a film of a first composition including an organic solvent, a precursor of a p-type organic semiconductor polymer, and the first semiconductor nanoparticles and thermally treating (e.g., heating) the film at a temperature of greater than or equal to about 110° C., (e.g., greater than or equal to about 120° C., or greater than or equal to about 140° C.) and less than or equal to about 180° C. to form a first layer; and

forming a film of a second composition including an organic solvent and the second semiconductor nanoparticles and removing the organic solvent from the film to form the second layer.

The forming of the first layer may not include a UV light irradiation. The UV light irradiation may be conducted by using of a UV light having a wavelength of less than or equal to about 400 nm.

In an embodiment, an electronic device (or a display device) may include the electroluminescent device.

The display device may include a portable terminal device, a monitor, a notebook computer, a television, an electric sign board, a camera, or an electronic component.

According to embodiments are provided an electroluminescent device capable of implementing improved electroluminescent properties (e.g., a maximum external quantum efficiency or a maximum luminance) and a life time characteristic, or a manufacturing method for the electroluminescent device, and an electronic device including the same. According to the manufacturing method of one embodiment, an improved solvent orthogonality can be secured, providing increased flexibility in the process of forming a multi-layered light emitting film, and realizing a desired multi-layered light emitting film structure even via an inkjet method.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1A is a schematic cross-sectional view of an electroluminescent device according to an embodiment;

FIG. 1B is a schematic cross-sectional view of an electroluminescent device according to an embodiment; and

FIG. 1C is a schematic cross-sectional view of an electroluminescent device according to an embodiment.

FIG. 2 is a schematic cross-sectional view of an electroluminescent device according to an embodiment;

FIG. 3 is a schematic cross-sectional view of an electroluminescent device according to an embodiment;

FIG. 4 shows a UV-Vis absorption spectrum for each of the precursors of the p-type organic semiconductor polymers.

FIG. 5 shows results for an AC-3 analysis for each of the precursors of the p-type organic semiconductor polymers.

FIG. 6 shows Electroluminescent properties of electroluminescent devices of Examples and Comparative Examples.

### DETAILED DESCRIPTION

Hereinafter, with reference to the accompanying drawings, various embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are assigned to the same or similar elements throughout the specification.

The size and thickness of each constituent element as shown in the drawings are indicated for better understanding and ease of description, and this disclosure is not necessarily limited to sizes or thicknesses as shown. In the drawings, the thickness of layers, films, panels, regions, etc., are exaggerated for clarity. And in the drawings, for convenience of description, the thickness of some layers and regions are exaggerated. The term “cross-sectional view” means a view in which a cross-section of the target part that is cut in a vertical direction is viewed from the side.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above” in an opposite direction of gravity.

Further, the singular includes the plural unless mentioned otherwise. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third,” etc., may be used herein to describe various elements, components, regions, layers, and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, values of a work function, a conduction band, or a lowest unoccupied molecular orbital (LUMO) (or valence band or highest occupied molecular orbital (HOMO)) energy level is expressed as an absolute value from a vacuum level. In addition, when the work function or the energy level is referred to be “deep,” “high” or “large,” the work function or the energy level has a large absolute value based on “0 electron volts (eV)” of the vacuum level, while when the work function or the energy level is referred to be “shallow,” “low,” or “small,” the work function or energy level has a small absolute value based on “0 eV” of the vacuum level.

As used herein, the average (value) may be mean or median. In an embodiment, the average (value) may be a mean average.

As used herein, the term “peak emission wavelength” is the wavelength at which a given emission spectrum of the light reaches its maximum.

As used herein, when a definition is not otherwise provided, “substituted” refers to replacement of a, e.g., at least one, hydrogen of a compound or the corresponding moiety by a C1 to C30 alkyl group, a C2 to C30 alkenyl group, a C2 to C30 alkynyl group, a C6 to C30 aryl group, a C4 (or C7) to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM′, wherein M′ is an organic or inorganic cation), a sulfonic acid group (—SO₃H) or a salt thereof (—SO₃M′, wherein M′ is an organic or inorganic cation), a phosphoric acid group (—PO₃H₂) or a salt thereof (—PO₃M′H or —PO₃M′₂, wherein M′ is an organic or inorganic cation), or a combination thereof.

As used herein, the term “a combination thereof” may refer to a mixture, an alloy, inclusion of at least two chemical moieties or groups as recited, or a moiety that can be formed by linking at least two selected from the recited chemical moieties or groups.

As used herein, when a definition is not otherwise provided, a “hydrocarbon” or “hydrocarbon group” refers to a compound or a group containing carbon and hydrogen (e.g., an aliphatic group such as an alkyl, alkenyl, or alkynyl group, an aromatic group such as an aryl group, or an alicyclic group). The hydrocarbon group may be a monovalent group or a group having a valence of greater than one formed by removal of one or more hydrogen atoms from alkane, alkene, alkyne, or arene. In the hydrocarbon group of an embodiment, a, e.g., at least one, methylene may be replaced by an oxide moiety, a carbonyl moiety, an ester moiety, —NH—, or a combination thereof. Unless otherwise stated to the contrary, the hydrocarbon (alkyl, alkenyl, alkynyl, aryl, or alicyclic) group may have 1 to 60, 2 to 32, 3 to 24, or 4 to 12 carbon atoms.

In an embodiment, “aliphatic hydrocarbon” may be a saturated or unsaturated, linear or branched C1 to C30 hydrocarbon group including (or consisting of) carbon and hydrogen.

In an embodiment, “aromatic” or “aromatic group” may include a C6 to C30 aryl or arylene group or a C3 to C30 heteroaryl or heteroarylene group.

In an embodiment, “alicyclic group” may refer to not only a saturated or unsaturated C3 to C30 cyclic group consisting of carbon and hydrogen but also a saturated or unsaturated C3 to C30 heterocyclic group that further includes a hetero atom in addition to carbon and hydrogen.

As used herein, when a definition is not otherwise provided, “alkyl” refers to a linear or branched saturated monovalent hydrocarbon group (methyl, ethyl hexyl, etc.). Unless specified otherwise, an alkyl group has from 1 to 50 carbon atoms, or 3 to 18 carbon atoms, or 5 to 12 carbon atoms.

As used herein, when a definition is not otherwise provided, “alkenyl” refers to a linear or branched monovalent hydrocarbon group having one or more carbon-carbon double bond. In an embodiment, an alkenyl group may have from 2 to 50 carbon atoms, or 3 to 18 carbon atoms, or 5 to 12 carbon atoms.

As used herein, when a definition is not otherwise provided, “alkynyl” refers to a linear or branched monovalent hydrocarbon group having one or more carbon-carbon triple bond. In an embodiment, an alkynyl group may have from 2 to 50 carbon atoms, or 3 to 18 carbon atoms, or 5 to 12 carbon atoms.

As used herein, when a definition is not otherwise provided, “aryl” or “heteroaryl” refers to a group formed by removal of a, e.g., at least one, hydrogen from an aromatic group (e.g., a phenyl, naphthyl, pyridyl group). In an embodiment, an aryl group may have from 6 to 50 carbon atoms, or 6 to 18 carbon atoms, or 6 to 12 carbon atoms. In an embodiment, a heteroaryl group may have from 5 to 50 carbon atoms, or 5 to 18 carbon atoms, or 5 to 12 carbon atoms.

As used herein, “cyclic group” refers to an aromatic, alicyclic, or heterocyclic group with one or more rings, which may include two or more condensed rings.

As used herein, when a definition is not otherwise provided, “hetero” refers to a group including 1 to 3 heteroatoms of N, O, S, Si, P, or a combination thereof. In an embodiment, the wording “aromatic” refers to not only the case where a group consists of carbon but also the case where a group further includes a hetero atom in addition to carbon. In an embodiment, the wording “alicyclic” refers to not only the case where a group consists of carbon but also the case where a group further includes a hetero atom in addition to carbon.

In an embodiment, “alkylene group” may be a straight or branched saturated aliphatic hydrocarbon group having at least two valences and optionally substituted with a, e.g., at least one, substituent.

As used herein, when a definition is not otherwise provided, “alkoxy” means an alkyl group linked via an oxygen (i.e., alkyl-O—), such as a methoxy, ethoxy, or sec-butyloxy group.

As used herein, when a definition is not otherwise provided, “amine group” may be represented by —NRR, wherein each R is independently hydrogen, a C1 to C12 alkyl group, a C7 to C20 alkylaryl group, a C7 to C20 arylalkyl group, or a C6 to C18 aryl group.

As used herein, a description of not containing harmful heavy metals such as cadmium may refer to a concentration of cadmium (or a corresponding heavy metal) of less than or equal to about 100 parts per million by weight (ppmw), less than or equal to about 50 ppmw, less than or equal to about 10 ppmw, or about zero ppmw. In an embodiment, substantially no cadmium (or other heavy metal) is present, or, if present, in an amount or impurity level below the detection limit of a given detection means.

In an embodiment, numerical ranges stated herein are inclusive of the endpoint of each range. As used herein, the upper and lower endpoints set forth for various numerical values may be independently combined to provide a range.

As used herein, “substantially” or “about” means not only the stated value, but also the mean within an acceptable range of deviations, considering the errors associated with the corresponding measurement and the measurement of the measured value. For example, “about” can mean within ±10%, 5%, 3%, or 1% or within standard deviation of the stated value.

As used herein, a nanoparticle is a structure having a, e.g., at least one, region or characteristic dimension with a nanoscale dimension, for example, of less than or equal to about 500 nm. In an embodiment, the dimension of the nanoparticle may be less than about 300 nm, less than about 250 nm, less than about 150 nm, less than about 100 nm, less than about 50 nm, or less than about nm. The structures may have any suitable shape.

Unless otherwise specified herein, the nanoparticles or semiconductor nanoparticles may have any suitable shape, such as nanowires, nanorods, nanotubes, multi-pod type shapes having two or more pods, nanodots (or quantum dots), etc., and are not particularly limited. The nanoparticles may be, for example, substantially crystalline, substantially monocrystalline, polycrystalline, amorphous, or a combination thereof.

For example, semiconductor nanoparticles such as quantum dots may exhibit quantum confinement or exciton confinement. In the present specification, the term “nanoparticle or quantum dot” are not limited in shapes thereof unless specifically defined. Semiconductor nanoparticles, such as quantum dot, may have a size smaller than a diameter of Bohr excitation in the bulk crystal of the same material, and may exhibit a quantum confinement effect. A quantum dot may emit light corresponding to a bandgap energy thereof by controlling the size of the emission center of the nanocrystals.

Herein, T50 refers to a time for luminance of a given device to decrease to 50% of the initial luminance when the device is driven at a predetermined initial luminance.

Herein, T90 refers to a time for luminance of a given device to decrease to 90% of the initial luminance when the device is driven at a predetermined initial luminance.

As used herein, the upper and lower endpoints set forth for each of various values may be independently combined to provide a range.

Herein, external quantum efficiency (EQE) refers to a ratio of the number of photons emitted from a light emitting diode (LED) to the number of electrons passing through the device. EQE may be a criteria of how efficiently the light emitting diode converts the electrons into emitted photons. In an embodiment, EQE may be determined based on the following equation:

EQE=(Injection efficiency)×(Solid state quantum yield)×(Extraction efficiency)

Injection efficiency=proportion of electrons passing through the device that are injected into the active region;

Solid state quantum yield=proportion of all electron-hole recombinations in the active region that are radiative and produce photons; and

Extraction efficiency=proportion of photons generated in the active region that escape from the device.

Herein, the maximum external quantum efficiency refers to the maximum value of the external quantum efficiency.

Herein, the maximum luminance refers to a maximum value of luminance that the device can achieve.

Herein, quantum efficiency is a term used interchangeably with quantum yield. Quantum efficiency (or quantum yield) may be measured either in solution or in the solid state (in a composite). In an embodiment, quantum efficiency (or quantum yield) is the ratio of photons emitted to photons absorbed by the nanostructure or population thereof. In an embodiment, quantum efficiency may be measured by any suitable method. For example, for fluorescence quantum yield or efficiency, there may be two methods: an absolute method and a relative method.

In the absolute method, quantum efficiency is obtained by detecting the fluorescence of all samples through an integrating sphere. In the relative method, the quantum efficiency of the unknown sample is calculated by comparing the fluorescence intensity of a standard dye (standard sample) with the fluorescence intensity of the unknown sample. Coumarin 153, Coumarin 545, Rhodamine 101 inner salt, Anthracene and Rhodamine 6G may be used as standard dyes according to photoluminescence (PL) wavelengths thereof, but the present disclosure is not limited thereto.

A bandgap energy of semiconductor nanocrystal particles may be changed according to sizes, structures, and compositions of nanocrystals. A semiconductor nanocrystal may be used as light emitting materials in various fields of a display device, an energy device, or a bio light emitting device, for example.

A semiconductor nanocrystal particle-based light emitting device (hereinafter, also referred to as a QD-LED) that emits light by application of a voltage includes semiconductor nanocrystal particles as a light emitting material. A QD-LED relies on a different emission principle than that of an organic light emitting diode (OLED) emitting light by using an organic material as an emission center with the former used as a next generation display device, and exhibit, purer colors (for example, red, green, and/or blue) and improved color reproducibility. Moreover, a QD-LED may be manufactured at a reduced cost by including a solution process, may be based on an inorganic material, and may be expected to exhibit increased stability, however, technology development for improving QD-LED properties and life-span characteristics remains of interest.

In some instances, quantum dots that are configured to exhibit electroluminescent properties at a desirable performance level may contain harmful heavy metals such as cadmium (Cd), lead, mercury, or a combination thereof. Accordingly, it is desirable to provide a light emitting device or a display device having a light emitting layer substantially free of the harmful heavy metal.

An electroluminescent device according to an embodiment is a luminescent light emitting device configured to emit a desired light by applying a voltage to the device without the need to include a light (irradiation) source.

According to an embodiment, an electroluminescent device or an electrically conductive layered structure capable of implementing improved electroluminescent properties and lifetime properties is provided. In an embodiment, the layered structure may prevent or suppress a resistance change resulting from a charging phenomenon for example in an electroluminescent device.

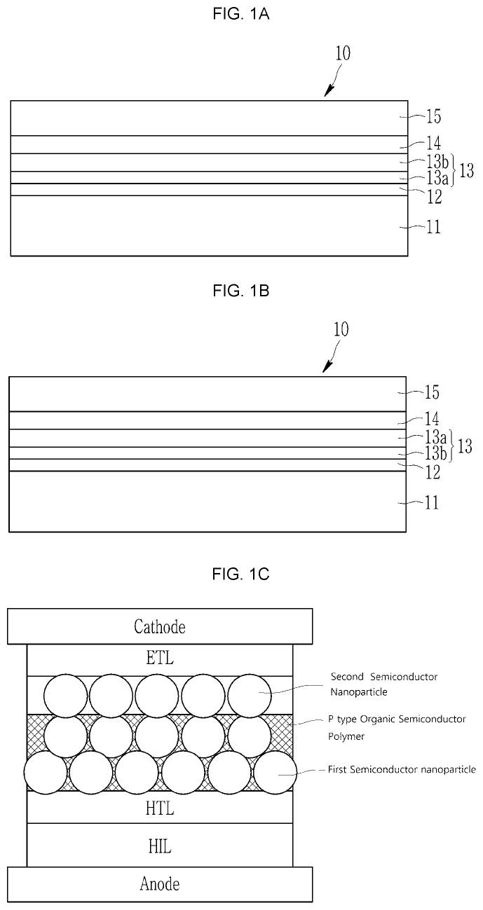

In an embodiment, the electroluminescent devices of FIG. 1A and FIG. 1B includes a first electrode 11 and a second electrode 15 spaced apart (e.g., opposite to each other); a multi-layered light emitting film 13 disposed between the first electrode and the second electrode and including a plurality of semiconductor nanoparticles; and an electron auxiliary layer 14 (e.g., an electron transport layer) between the light emitting layer 13 and the second electrode 15. The electron auxiliary layer may include the electron transport layer. The electroluminescent device 10 may further include a hole auxiliary layer 12 between the multi-layered light emitting film 13 and the first electrode 11. The hole auxiliary layer 12 may include a hole transport layer (including, for example, an organic compound), a hole injection layer, or a combination thereof.

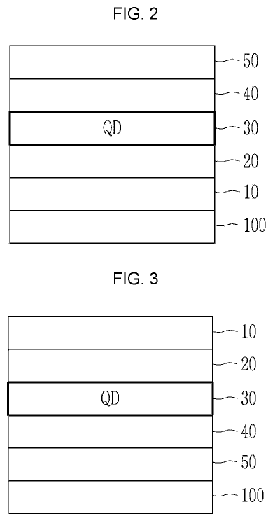

In the electroluminescent device of FIGS. 2 and 3, the first electrode 10 or the second electrode 50 may be disposed on a (transparent) substrate 100, respectively. The transparent substrate may be a light extraction surface. Referring to FIGS. 2 and 3, the light emitting layer 30 may be disposed between the first electrode 10 and the second electrode 50. The second electrode 50 may include an electron injection conductor. The first electrode 10 may include a hole injection conductor. The work functions of the electron/hole injection conductors included in the second electrode and the first electrode may be appropriately adjusted and are not particularly limited. For example, the second electrode may have a small work function and the first electrode may have a relatively large work function, or vice versa.

The electron/hole injection conductors may include a metal-based material (e.g., a metal, a metal compound, an alloy, or a combination thereof) (aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The electrode may be patterned. The first electrode, the second electrode, or a combination thereof may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and for example, less than or equal to about 99%, or less than or equal to about 95%). The substrate may further include a region for a blue pixel, a region for a red pixel, a region for a green pixel, or a combination thereof. A thin film transistor may be disposed in each of the stated regions of the substrate, and one of a source electrode and a drain electrode of the thin film transistor may be electrically connected to the first electrode or the second electrode.

The light-transmitting electrode may be disposed on a (e.g., insulating) transparent substrate. The substrate may be rigid or flexible substrate. Accordingly, the substrate may be plastic, glass, or a metal.

The light-transmitting electrode may be made of, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a thin metal thin film of a single layer or a plurality of layers, but is not limited thereto. When one of the first electrode and the second electrode is an opaque electrode, the opaque electrode may be made of an opaque conductor such as aluminum (Al), a lithium-aluminum (Li:Al) alloy, a magnesium-silver alloy (Mg;Ag), and lithium fluoride-aluminum (LiF:Al).

The thickness of each electrode (e.g., the first electrode, the second electrode, or each of the first electrode and the second electrode) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

A multi-layered light emitting film 13 (FIGS. 1A and 1B) or 30 is disposed between the first electrode 11 and the second electrode 15 (or e.g., the first electrode 10 and the second electrode 50 of FIGS. 2 and 3), respectively. The multi-layered light emitting film includes a semiconductor nanoparticle (e.g., a semiconductor nanoparticle emitting light of a predetermined peak emission wavelength, such as a blue light emitting nanoparticle, a red light emitting nanoparticle, or a green light emitting nanoparticle).

The multilayer light emitting film is configured to emit a first light having a predetermined peak emission wavelength (e.g., having one emitting peak).

The first light may be blue light. An emission peak of the first light or the peak emission wavelength of the first light may exist or be present in a blue wavelength region. The blue wavelength region may be greater than or equal to about 440 nm, greater than or equal to about 445 nm, greater than or equal to about 450 nm, or greater than or equal to about 445 nm. The blue wavelength region may be less than or equal to about 480 nm, less than or equal to about 475 nm, less than or equal to about 470 nm, less than or equal to about 465 nm, less than or equal to about 460 nm, or less than or equal to about 457 nm.

The first light may be green light. An emission peak of the first light or the peak emission wavelength of the first light may exist or be present in a green wavelength region. The green wavelength region may be greater than or equal to about 500 nm, greater than or equal to about 505 nm, greater than or equal to about 510 nm, greater than or equal to about 515 nm, or greater than or equal to about 520 nm. The green wavelength region may be less than or equal to about 580 nm, less than or equal to about 560 nm, less than or equal to about 555 nm, less than or equal to about 550 nm, less than or equal to about 545 nm, or less than or equal to about 540 nm.

The first light may be red light. An emission peak of the first light or the peak emission wavelength of the first light may exist or be present in a red wavelength region. The red wavelength region may be greater than or equal to about 600 nm, greater than or equal to about 605 nm, greater than or equal to about 610 nm, greater than or equal to about 615 nm, greater than or equal to about 620 nm, or greater than or equal to about 620 nm. The red wavelength region may be less than or equal to about 680 nm, less than or equal to about 675 nm, less than or equal to about 670 nm, less than or equal to about 665 nm, less than or equal to about 660 nm, less than or equal to about 655 nm, less than or equal to about 650 nm, less than or equal to about 645 nm, less than or equal to about 640 nm, or less than or equal to about 635 nm.

A full width at half maximum of an emission peak of the first light may be greater than or equal to about 5 nm, greater than or equal to about 10 nm, greater than or equal to about 15 nm, or greater than or equal to about 20 nm. The full width at half maximum may be less than or equal to about 50 nm, less than or equal to about 45 nm, less than or equal to about 40 nm, less than or equal to about 35 nm, less than or equal to about 30 nm, or less than or equal to about 25 nm.

The first light may not be a mixed light (e.g., mixed light of green light and red light).

The multi-layered light emitting film may be patterned. In an embodiment, the patterned, multi-layered light emitting film may include a multi-layered blue light emitting film (e.g., disposed within a blue pixel in a display device to be described herein), a multi-layered red light emitting film (e.g., disposed within a red pixel in a display device to be described herein), a multi-layered green light emitting film (e.g., disposed within a green pixel in a display device to be described herein), or a combination thereof. Each of the multi-layered light emitting films may be (e.g., optically) separated from an adjacent light emitting layer by a partition wall. In an embodiment, a partition wall such as a black matrix may be disposed between the different color emitting films, e.g., the multi-layered red light emitting film, the multi-layered green light emitting film, and the multi-layered blue light emitting film. In an embodiment, the multi-layered red light emitting film, the multi-layered green light emitting film, and the multi-layered blue light emitting film may each be optically isolated.

A QD-LED has been attracting an attention as a type of light emitting device that does not require a separate light source. The QD-LED can provide improved physical properties (e.g., color reproducibility or color purity) compared to an OLED. It is desirable to develop a QD-LED that can realize desired device properties (e.g., electroluminescent properties and/or lifespan) without environmental issues (e.g., caused by a considerable use of toxic heavy metals such as cadmium).

For example, in the case of a QD-LED that includes a cadmium free semiconductor nanoparticle (e.g., semiconductor nanoparticles or quantum dots) as a light-emitting material, an improvement in terms of life and electroluminescence properties may be desirable. The electroluminescent device according to an embodiment may achieve a desired level of life and/or electroluminescent property by having the feature(s) described herein. Without wishing to be bound by any theory, in one implementation of an electroluminescent device, the multilayer light-emitting film may include p-n junction, thereby inducing an efficient e/h recombination.

For an inclusion of a p-n junction, a nanoparticle layer capable of exhibiting relatively p-type property and a nanoparticle layer capable of relatively n-type properties may be stacked, for example, sequentially or adjacent to each other. For example, one layer of nanoparticles having a relatively shorter alkyl-chain ligand placed on the surfaces of the nanoparticles may be formed. Then, another layer of nanoparticles having a relatively longer alkyl-chain ligand placed on the surfaces of the nanoparticles may formed on the one layer. Accordingly, a layer of nanoparticles blended with a hole transporting material, and a layer of nanoparticles blended with an electron transport material are disposed as a stack. However, in the production of the QD LED, the formation of a light emitting layer containing (semiconductor) nanoparticles may be carried out by a solution process and based on the solution process of the prior art, the formation of a p-type layer/n-type layer may be considerably limited.

For example, semiconductor nanoparticles with short ligands placed on the surface thereof are difficult to form a p-type emission layer with a conventional solution process due to a decrease in colloidal stability. In an embodiment, a semiconductor nanoparticle with a native ligand on a surface may be used to form a film, which may be subject to a process of removing or replacing a portion of the native ligand (e.g., a spin-dry process) to obtain a p-type light emitting film. However, the present inventors have found that in light of an inkjet printing process, it may be much more advantageous to form a p-type light emitting layer by adding a hole transporting material. In particular, where a small molecular weight organic hole transport material is included in the p-type nanoparticle-based light emitting layer, the forming of an n-type light emitting layer on the p-type light emitting layer, for example, while maintaining its thin film morphology may be quite difficult unless a solvent capable of providing an appropriate orthogonality (e.g., orthogonal solvent) is used. That is, the orthogonal solvent may form a nanoparticle dispersion and at the same time may not substantially affect the already formed lower emission layer (for example, the already formed p-type emission layer). When a solvent that does not have a proper solvent orthogonality is used, formation of the upper emission layer may result in undesired damage to the lower emission layer.

According to an embodiment, an electroluminescent device is described in which the above-described problems are addressed. The electroluminescent device of an embodiment includes a light emitting element having a multilayered structure as described herein, and provides improved light emitting properties and/or life characteristics. In an embodiment, the organic hole transport material may be easily mixed with a semiconductor nanoparticle to provide a uniform and thin film, and improved solvent orthogonality may be secured by a heat treatment after a thin film formation.

In an electroluminescent device of an embodiment, a multilayered light emitting film 13 includes a first layer 13a containing a plurality of first semiconductor nanoparticles and a second layer 13b containing a plurality of second semiconductor nanoparticles. Referring to FIG. 1A, a second layer 13b may be disposed between the first layer 13a and the electron auxiliary layer 14. Referring to FIG. 1B, a first layer 13a may be disposed between the second layer 13b and the electron auxiliary layer 14.

In an embodiment, the plurality of first semiconductor nanoparticles in the first layer 13a may be surrounded by a p-type organic semiconductor polymer, and in the second layer, a plurality of second semiconductor nanoparticles may be disposed adjacent to (or in contact with, e.g., being spaced by native ligands) the other (e.g., without the p-type organic semiconductor polymer positioned between the particles. See FIG. 10.

The second layer may not include the p-type organic semiconductor polymer.

The first semiconductor nanoparticles and the second semiconductor nanoparticles may have substantially the same composition. The first semiconductor nanoparticles and the second semiconductor nanoparticles may have substantially the same peak emission wavelength. Hereinafter, the term “the semiconductor nanoparticles” may refer to the first semiconductor nanoparticles or the second semiconductor nanoparticles.

In an embodiment, in the light emitting layer, the semiconductor nanoparticles may exhibit a zinc blende crystal structure, a perovskite crystal structure, or a combination thereof.

The light emitting layer or the semiconductor nanoparticle may not include cadmium. The light emitting layer or the semiconductor nanoparticle may not include mercury, lead, or a combination thereof.

In an embodiment, the semiconductor nanoparticles may have a core-shell structure. The semiconductor nanoparticles may include a core including a first semiconductor nanocrystal and a shell including a second semiconductor nanocrystal disposed on the core and having a composition different from that of the first semiconductor nanocrystal.

The semiconductor nanoparticle (e.g., the first semiconductor nanocrystal, the second semiconductor nanocrystal, or a combination thereof) may include a Group II-VI compound, a Group III-V compound, a Group IV-VI compound, a Group IV element or compound, a Group compound, a Group I-II-IV-VI compound, or a combination thereof. The light emitting layer (or semiconductor nanoparticle, first semiconductor nanocrystal, or second semiconductor nanocrystal) may not contain harmful heavy metals such as cadmium, lead, mercury, or a combination thereof.

The Group II-VI compound may be a binary compound such as ZnS, ZnSe, ZnTe, ZnO, HgS, HgSe, HgTe, MgSe, MgS, or a combination thereof; a ternary compound such as ZnSeS, ZnSeTe, ZnSTe, HgSeS, HgSeTe, HgSTe, HgZnS, HgZnSe, HgZnTe, MgZnSe, MgZnS, or a combination thereof; a quaternary compound such as HgZnTeS, HgZnSeS, HgZnSeTe, HgZnSTe, or a combination thereof; or a combination thereof. The Group II-VI compound may further include a Group III metal.

The Group III-V compound may be a binary compound such as GaN, GaP, GaAs, GaSb, AlN, AlP, AlAs, AlSb, InN, InP, InAs, InSb, or a combination thereof; a ternary compound such as GaNP, GaNAs, GaNSb, GaPAs, GaPSb, AlNP, AlNAs, AlNSb, AlPAs, AlPSb, InNP, InNAs, InNSb, InPAs, InPSb, or a combination thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof.

The Group III-V compound may further include a Group II element. An example of a first semiconductor nanocrystal is InZnP.

The Group IV-VI compound may be a binary compound such as SnS, SnSe, SnTe, or a combination thereof; a ternary compound such as SnSeS, SnSeTe, SnSTe, or a combination thereof; a quaternary compound such as SnSSeTe; or a combination thereof.

Examples of the Group compound include CuInSe₂, CuInS₂, CuInGaSe, and CuInGaS, but are not limited thereto.

Examples of the group I-II-IV-VI compound include, but are not limited to, CuZnSnSe and CuZnSnS.

The Group IV element or compound is a single element such as Si, Ge, or a combination thereof; a binary compound such as SiC, SiGe, or a combination thereof; or a combination of a single element and a binary compound.

In an embodiment, the first semiconductor nanocrystal may include a metal including indium, zinc, or a combination thereof and a non-metal including phosphorus, selenium, tellurium, sulfur, or a combination thereof. In an embodiment, the second semiconductor nanocrystal may include a metal including indium, zinc, or a combination thereof, and a non-metal including phosphorus, selenium, tellurium, sulfur, or a combination thereof.

In an embodiment, the first semiconductor nanocrystal may include InP, InZnP, ZnSe, ZnSeS, ZnSeTe, or a combination thereof; the second semiconductor nanocrystal may include ZnSe, ZnSeS, ZnS, ZnTeSe, or a combination thereof; or a combination thereof. In an embodiment, the shell may include zinc, sulfur, and optionally further include selenium in the outermost layer.

In an embodiment, the semiconductor nanoparticles may emit blue or green light and have a core including ZnSeTe, ZnSe, or a combination thereof and a shell including zinc chalcogenide (e.g., ZnS, ZnSe, ZnSeS, or a combination thereof). An amount of sulfur in the shell may increase or decrease in the radial direction (i.e., in a direction from the core toward the surface).

In an embodiment, the semiconductor nanoparticles may emit red or green light, the core may include InP, InZnP, or a combination thereof, and the shell may include a Group II metal including zinc and a non-metal including sulfur, selenium, or a combination thereof.

In an embodiment, when the semiconductor nanoparticles have a core-shell structure, an alloyed layer may or may not be present at the interface between the core and the shell. The alloyed layer may be a homogeneous alloy or may be a gradient alloy. In the gradient alloy, a concentration of elements present in the shell may have a concentration gradient that changes in the radial direction (e.g., decreases or increases in a direction toward the core).

In an embodiment, the shell may have a composition that varies in a radial direction. In an embodiment, the shell may be a multilayered shell including two or more layers. In the multi-layered shell, adjacent layers may have different compositions than the other. In the multi-layered shell, a, e.g., at least one layer may independently include a semiconductor nanocrystal having a single composition. In the multilayered shell, a, e.g., at least one layer may independently have an alloyed semiconductor nanocrystal. In the multilayered shell, a e.g., at least one layer, may have a concentration gradient that radially changes in terms of a composition of a semiconductor nanocrystal.

In the core-shell structured semiconductor nanoparticles, the bandgap energy of the shell material may be greater than that of the core material but is not limited thereto. The bandgap energy of the shell material may be smaller than that of the core material. In the case of the multi-layered shell, the bandgap energy of the outermost layer material of the shell may be greater than those of the core and/or the inner layer material of the shell (i.e., layers that are closer to the core). In the case of the multilayered shell, a semiconductor nanocrystal of each layer may be selected to have an appropriate bandgap, thereby effectively exhibiting a quantum confinement effect.

The semiconductor nanoparticles of an embodiment may include, for example, an organic ligand, an organic solvent, or a combination thereof, in a state in which they are bonded or coordinated to the surface.

In an embodiment, an absorption/emission wavelength of the semiconductor nanoparticle may be controlled, for example, by adjusting composition, size, or a combination of composition and size of the semiconductor nanoparticle. The semiconductor nanoparticles included in the multi-layered light emitting film 13 or 30 may be configured to emit light of a desired color. The semiconductor nanoparticles may include blue light emitting semiconductor nanoparticles, green light emitting semiconductor nanoparticles, or red light emitting semiconductor nanoparticles. Details of the wavelength of the blue light, the green light, or the red light are the same as described herein.

The semiconductor nanoparticle or the light emitting film may exhibit a luminescent (e.g. photoluminescent or electroluminescent) spectrum having a relatively narrow full width at half maximum. In an embodiment, the semiconductor nanoparticle or the light emitting film may have a full width at half maximum of less than or equal to about 45 nm, for example less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm, in a photoluminescence spectrum thereof. The full width at half maximum may be greater than or equal to about 1 nm, greater than or equal to about 5 nm, greater than or equal to about 10 nm, greater than or equal to about 15 nm, or greater than or equal to about 20 nm.

The semiconductor nanoparticle or the light emitting film may have (e.g., be configured to implement) a quantum yield of greater than or equal to about 10%, for example, greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 90%, or about 100%.

The semiconductor nanoparticle may have a size (e.g., a particle diameter in the case of a substantially spherical particle or a particle diameter calculated from a two-dimensional area confirmed by electron microscopy analysis in the case of a non-spherical particle) of greater than or equal to about 1 nm and less than or equal to about 100 nm. In an embodiment, the semiconductor nanoparticle may have a size or an average size (hereinafter, “size”) of about 1 nm to about 50 nm, for example, 2 nm (or 3 nm) to 35 nm. In an embodiment, the size of the semiconductor nanoparticle may be greater than or equal to about 1 nm, greater than or equal to about 2 nm, greater than or equal to about 3 nm, greater than or equal to about 4 nm, or greater than or equal to about 5 nm. In an embodiment, the size of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, or less than or equal to about 15 nm.

The semiconductor nanoparticle may have any suitable shape. In an embodiment, the shape of the semiconductor nanoparticle may be a sphere, a polyhedron, a pyramid, a multi-pod, a cube, a nanotube, a nanowire, a nanofiber, a nanosheet, a nanoplate, or a combination thereof.

The semiconductor nanoparticle may be synthesized by any suitable method. For example, the semiconductor nanocrystal having a size of several nanometers may be synthesized through a wet chemical process. In the wet chemical process, crystal particles are grown by reacting precursor materials in an organic solvent, and growth of crystals may be controlled by coordinating the organic solvent or ligand compound on the surface of the semiconductor nanocrystals.

In an embodiment, for example, the method of preparing the semiconductor nanoparticles having a core-shell structure may include: obtaining a core; preparing a first shell precursor solution containing a first shell precursor containing a metal (e.g., zinc) and an organic ligand; preparing a second shell precursor containing a non-metal element (e.g., sulfur, selenium, or a combination thereof); and heating the first shell precursor solution to a reaction temperature (e.g., greater than or equal to about 180° C., greater than or equal to about 200° C., greater than or equal to about 240° C., or greater than or equal to about 280° C. to less than or equal to about 360° C., less than or equal to about 340° C., or less than or equal to about 320° C.) and adding the core and the second shell precursor to form a shell of a second semiconductor nanocrystal on the first semiconductor nanocrystal core. In the semiconductor nanoparticles of embodiment, the core may be manufactured by an appropriate method known to those of ordinary skill. The method may further include preparing a core solution by separating the core from the reaction system used for a preparation thereof and dispersing the core in an organic solvent.

In an embodiment, for shell formation, a solvent and optionally a ligand compound may be heated (or vacuum-treated) under vacuum to a predetermined temperature (e.g., 100° C. or higher), and may be heated to a predetermined temperature (e.g., 100° C. or higher) after converting a reaction atmosphere for the shell formation to an inert gas atmosphere. Subsequently, the core is added thereto, and the shell precursors are sequentially or simultaneously added onto the core and then, heated at a predetermined reaction temperature to form a core-shell nanocrystal. The shell precursors may be sequentially introduced to the reaction mixture in different proportions and at different times during the reaction.

The organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctylphosphine) substituted with a, e.g., at least one (e.g., 1, 2, or 3), C6 to C22 alkyl group, a phosphine oxide (e.g., trioctylphosphine oxide) substituted with a (e.g., 1, 2, or 3) C6 to C22 alkyl group, a C12 to C22 aromatic ether such as phenyl ether or benzyl ether, or a combination thereof. A combination including more than one type of organic solvent may be used,

The organic ligand may coordinate the surfaces of the prepared semiconductor nanoparticles and allow the semiconductor nanoparticles to be well dispersed in the solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, (wherein R and R′ are each independently a substituted or unsubstituted C1 or greater, C6 or greater, or C10 or greater and C40 or less, C35 or less, or C25 or less aliphatic hydrocarbon, or a substituted or unsubstituted C6 to C40 aromatic hydrocarbon, or a combination thereof), or a combination thereof. In an embodiment, at least two different ligands may be used.

The semiconductor nanocrystals may be recovered by adding an amount of nonsolvent, for example, to remove excess organic matter, e.g., ligand, not coordinated or bound to the surface. The semiconductor nanocrystals may then be separated by centrifuging the resulting mixture. The nonsolvent may be a polar solvent that is miscible with the solvent used in the core formation reaction, shell formation reaction, or a combination thereof, and is not capable of dispersing the prepared nanocrystals. The nonsolvent may be selected depending on, e.g., taking into consideration, the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, ethylene glycol, a solvent having a similar solubility parameter to the foregoing solvents, or a combination thereof. The obtained semiconductor nanocrystal particles may be separated through centrifugation, sedimentation, chromatography, or distillation. The separated nanocrystals may be added to a washing solvent and then isolated, if desired. The washing solvent has no particular limit and may have a similar solubility parameter to that of the ligand and may, for example, include hexane, heptane, octane, chloroform, toluene, or benzene.

The semiconductor nanoparticles may be water-insoluble or non-dispersible in water, the aforementioned nonsolvent, or a combination thereof. The semiconductor nanoparticles may be dispersed in the aforementioned organic solvent. In an embodiment, the aforementioned semiconductor nanoparticles may be dispersed in a substituted or unsubstituted C6 to C40 aliphatic hydrocarbon, a substituted or unsubstituted C6 to C40 aromatic hydrocarbon, or a combination thereof.

The surface of the prepared semiconductor nanoparticles may be treated with a halogen compound. By halogen treatment, some organic ligands present in the semiconductor nanoparticles may be replaced with halogen. The halogen-treated semiconductor nanoparticles may contain a reduced amount of organic ligand. The halogen treatment may be performed by contacting semiconductor nanoparticles with a halogen compound (e.g., a metal halide such as zinc chloride) at a predetermined temperature, for example, about 30° C. to about 100° C., or about 50° C. to about 150° C. in an organic solvent. The halogen-treated semiconductor nanoparticles may be separated using the aforementioned nonsolvent and separation methods.

In an embodiment, the first layer 13a of the multi-layered light emitting film includes an organic semiconductor polymer surrounding a plurality of the first semiconductor nanoparticles. For example, many of the first semiconductor nanoparticles may be embedded or dispersed in the organic semiconductor polymer. In an embodiment, the first layer 13a may be provided by forming a thin film with a desired thickness from a composition comprising a hole transporting organic small molecule with a reactive moiety and the first semiconductor nanoparticles, and then thermally treating the formed thin film. Surprisingly, the present inventors have found that the hole transporting organic small molecule with a reactive moiety may form a p-type organic semiconductor polymer surrounding the first semiconductor nanoparticles by the thermal treatment. Moreover, the addition hole transporting organic small molecule may not adversely affect the luminance properties of the nanoparticles. Surprisingly, the present inventors have found that the first layer including the p-type organic polymer is arranged to surround the first semiconductor nanoparticles, and thus, may provide an appropriate solvent orthogonality when present in a lower light emitting layer.

In an embodiment, the p-type organic semiconductor polymer may include a substituted or unsubstituted alkylene group, a substituted or unsubstituted phenylene group, a substituted or unsubstituted biphenylene group, —NR—, an ether group, or a combination thereof, and R is a substituted or unsubstituted C1-C30 aliphatic hydrocarbon group, a substituted or unsubstituted C3-C60 (or C30) aromatic hydrocarbon group, a substituted or unsubstituted C3-C30 heteroaromatic hydrocarbon group, a substituted or unsubstituted C3-C30 alicyclic hydrocarbon group, a substituted or unsubstituted C3-C30 heteroalicyclic hydrocarbon group, or a combination thereof.

In an embodiment, the organic semiconductor polymer may include a moiety represented by the following formulas in a repeating unit thereof:

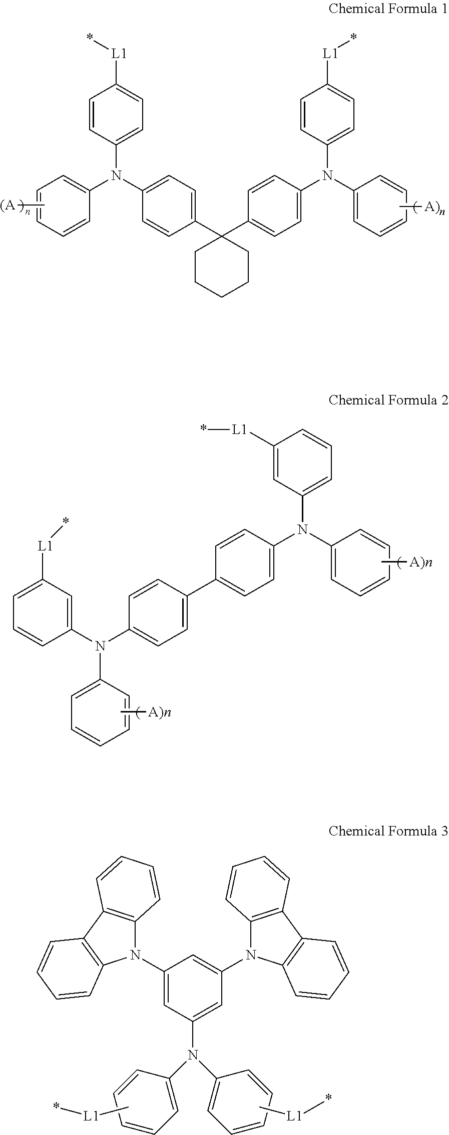

In the above formulas, each A is independently a C1 to C30 alkyl group, a C1 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen group (e.g., —F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM′, wherein M′ is an organic or inorganic cation), a sulfonic acid group (—SO₃H) or a salt thereof (—SO₃M′, wherein M′ is an organic or inorganic cation), a phosphoric acid group (—PO₃H₂) or a salt thereof (—PO₃M′H or —PO₃M′₂, wherein M′ is an organic or inorganic cation), or a combination thereof, e.g., a combination of two to three of the above.

n is 0 to 5, for example 0, 1, 2, 3, 4, or 5,

L1 is each independently, a substituted or unsubstituted C1-50 (or C2-C48, C3-C45, C4-C40, C5-C37, C6-C35, C7-C30, C8-C28, C9-C25, C10-C20, C11-C18, C12-C15, C13-14, or a combination of these) aliphatic hydrocarbon (e.g., alkylene, alkenylene, or alkynylene) group, —O—, —RO—, where R is a substituted or unsubstituted C1-50, such as C2-C48, C3-C45, C4-C40, C5-C37, C6-C35, C7-C30, C8-C28, C9-C25, C10-C20, C11-018, C12-C15, or C13-C14 aliphatic hydrocarbon group, —COO—, —NH—, —CONH—, —S—, or a combination thereof (e.g., a moiety formed by the foregoing groups),

and * is a portion connected to an adjacent repeating unit in the polymer or to the semiconductor nanoparticle (or a ligand on the surface of the semiconductor nanoparticle).

At least one methylene in the aliphatic hydrocarbon group described in L may be replaced by COO—, —NH—, —CONH—, —S—, or a combination thereof.

When n is 2 or more in Chemical Formulae 1 and 2, adjacent substituents may fuse with each other to form a ring (e.g., a benzene ring). In Chemical Formulae 1, 2, and 3, each aromatic ring (e.g., a phenyl group, a carbazole group, etc.) may further include an additional substituent. The additional substituents are as defined herein.

In an embodiment, the organic semiconductor polymer may be formed via an in-situ polymerization by a heat treatment of a compound including the aforementioned repeating unit and having a reactive group (hereinafter, a precursor of the organic semiconductor polymer). In an embodiment, the first semiconductor nanoparticles may be dispersed in the p-type organic semiconductor polymer. The reactor may induce a reaction between the compounds. The reactive group may induce a reaction with a ligand disposed on the surface of the semiconductor nanoparticle. The reactive group may include a carbon-carbon double bond, an epoxy group, a thiol group, a carbon-carbon triple bond, a ketone group, an aldehyde group, an epoxy alkane moiety, or a combination thereof (e.g., at least two of the foregoing groups). The carbon-carbon double bond may include a vinyl group, a (meth)acrylate group, or a combination thereof. The epoxy alkane moiety may include 1,2-epoxyethane, 1,3-epoxypropane, 1,4-epoxybutane, 1,5-epoxypentane, or a combination thereof. The polymerization reaction may include ring-opening polymerization, radical polymerization, or a combination thereof.

In an embodiment, the number of the repeating unit described herein in the p-type organic semiconductor polymer may be greater than or equal to about 2, greater than or equal to about 3, greater than or equal to about 4, greater than or equal to about 5, greater than or equal to about 6, greater than or equal to about 7, greater than or equal to about 8, greater than or equal to about 9, greater than or equal to about 10, greater than or equal to about 15, greater than or equal to about 20, or greater than or equal to about 25. The number of the repeating unit described herein in the p-type organic semiconductor polymer may be less than or equal to about 10000, less than or equal to about 5000, less than or equal to about 1000, less than or equal to about 800, less than or equal to about 500, less than or equal to about 400, less than or equal to about 300, less than or equal to about 200, less than or equal to about 100, less than or equal to about 90, less than or equal to about 50, or less than or equal to about 30.

A molecular weight of the p-type organic semiconductor polymer may be greater than or equal to about 500, greater than or equal to about 600, greater than or equal to about 700, greater than or equal to about 800, greater than or equal to about 900, greater than or equal to about 1000, greater than or equal to about 1100, greater than or equal to about 1200, greater than or equal to about 1300, greater than or equal to about 1400, greater than or equal to about 1500, greater than or equal to about 1600, greater than or equal to about 1700, greater than or equal to about 1800, greater than or equal to about 1900, greater than or equal to about 2000, greater than or equal to about 2500, greater than or equal to about 3000, greater than or equal to about 3500, or greater than or equal to about 4000. The molecular weight of the p-type organic semiconductor polymer may be less than or equal to about 500,000, less than or equal to about 300,000, less than or equal to about 200,000, less than or equal to about 100,000, less than or equal to about 50,000, less than or equal to about 10,000, less than or equal to about 8,000, less than or equal to about 6,000, less than or equal to about 4,000, less than or equal to about 2,000, or less than or equal to about 1,000. The molecular weight of the polymer may be a number average molecular weight or a weight average molecular weight.

In a non-limiting embodiment, a precursor for the p-type organic semiconductor polymer may include N4,N4′-Bis(4-(6-((3-ethyloxetan-3-yl)methoxy)hexyl)phenyl)-N4,N4′-diphenylbiphenyl-4,4′-diamine, N4,N4′-Bis(4-(6-((3-ethyloxetan-3-yl)methoxy)hexyloxy)phenyl)-N4,N4′-bis(4-methoxyphenyl)biphenyl-4,4′-diamine, N,N′-(4,4′-(Cyclohexane-1,1-diyl)bis (4,1-phenylene))bis(N-(4-(6-(2-ethyloxetan-2-yloxy)hexyl)phenyl)-3,4,5-trifluoroaniline), 3,5-Di-9H-carbazol-9-yl-N, N-bis[4-[[6-[(3-ethyl-3-oxetanyl)methoxy]hexyl]oxy]phenyl]benzenamine, or a combination thereof. The precursor of the p-type organic semiconductor polymer or its polymer may have various mobility and energy levels, and a light emitting layer and an interlayer may be formed with excellent miscibility with the semiconductor nanoparticles, improving electron/hole balancing, hole injection, and electron blocking properties in the light emitting layer. The precursor of the p-type organic semiconductor polymer may include a long chain alkyl group with an aromatic moiety, and may form a uniform mixture (e.g., a homogeneous mixture) in a solvent (e.g., an alkane solvent such as octane) capable of providing stable dispersibility for semiconductor nanoparticles.

A LUMO energy level of the precursor of the p-type organic semiconductor polymer may be less than about 3 eV, for example, less than or equal to about 2.95 eV, less than or equal to about 2.9 eV, less than or equal to about 2.85 eV, less than or equal to about 2.8 eV, less than or equal to about 2.75 eV, less than or equal to about 2.7 eV, less than or equal to about 2.65 eV, less than or equal to about 2.6 eV, or less than or equal to about 2.55 eV. The LUMO energy level of the precursor of the p-type organic semiconductor polymer may be greater than or equal to about 1.5 eV, greater than or equal to about 1.6 eV, greater than or equal to about 1.7 eV, greater than or equal to about 1.8 eV, greater than or equal to about 1.9 eV, greater than or equal to about 2 eV, greater than or equal to about 2.1 eV, greater than or equal to about 2.2 eV, greater than or equal to about 2.25 eV, greater than or equal to about 2.3 eV, greater than or equal to about 2.35 eV, greater than or equal to about 2.4 eV, greater than or equal to about 2.45 eV, greater than or equal to about 2.5 eV, or greater than or equal to about 2.6 eV.

A HOMO energy level of the precursor of the p-type organic semiconductor polymer may be from about 5.1 eV to about 7 eV, from about 5.2 eV to about 6.5 eV, from about 5.3 eV to about 6.2 eV, from about 5.4 eV to about 6.1 eV, from about 5.5 eV to about 6 eV, from about 5.6 eV to about 5.9 eV, from about 5.7 eV to about 5.8 eV, or a combined range thereof.

In an embodiment, the HOMO energy level may be a value measured by photo-electron spectroscopy in air (e.g., photoelectron spectrophotometer, model name AC3 manufactured by Riken Keiki Co. Ltd.). In a measurement involving the photoelectron spectroscopy analysis, when the photoelectron output is plotted on an X/Y axis, with horizontal axis as the UV energy applied, and the vertical axis as a standardized photoelectron yield ration, the result is a curved line rising with a specific slope of degree and the HOMO level is a value at which the base line meets a straight and extending line obtained from the dots in a region of the increasing slope. In an embodiment, the LUMO energy level may be calculated from the HOMO level measured by using the AC3 and a bandgap energy measured by using a UV-Vis absorption spectrum.

Surprisingly, the present inventors have found that the first layer in the light emitting film may have a desired level of resistance to a solvent (e.g., an alkane solvent) capable of dispersing the light-emitting nanostructure. Accordingly, the first layer may have a residual thickness percentage of greater than or equal to about 80% with respect to a C5-18 aliphatic hydrocarbon solvent, the residual thickness percentage being defined by the following equation:

residual thickness percentage=[B/A]×100

A: initial thickness of the first layer

B: a thickness of the first layer after being in contact with a given solvent for a predetermined time (e.g., for a time period of greater than or equal to about 5 and less than or equal to about 60 seconds).

The residual thickness percentage of the first layer may be greater than or equal to about 85%, greater than or equal to about 88%, greater than or equal to about 90%, greater than or equal to about 93%, greater than or equal to about 95%, greater than or equal to about 97%, or greater than or equal to about 99%. In an embodiment, the residual thickness percentage of the first layer may be 100%. This residual thickness percentage of the first layer may provide, for example, improved solvent orthogonality during the formation of the second layer including semiconductor nanoparticles being coordinated with an organic ligand.

A thickness of the first layer may be selected taking into consideration the first semiconductor nanoparticle, a desired thickness of the light emitting film or layer, desired electrical/optical properties thereof. A thickness of the first layer may be greater than or equal to about 5 nm, greater than or equal to about 7 nm, greater than or equal to about 9 nm, greater than or equal to about 11 nm, greater than or equal to about 13 nm, greater than or equal to about 15 nm, greater than or equal to about 17 nm, greater than or equal to about 19 nm, or greater than or equal to about 20 nm. A thickness of the first layer may be less than or equal to about 80 nm, less than or equal to about 65 nm, less than or equal to about 50 nm, less than or equal to about 45 nm, less than or equal to about 40 nm, less than or equal to about 35 nm, less than or equal to about 30 nm, less than or equal to about 25 nm, or less than or equal to about 20 nm. A thickness of the first layer may be in a range provided by the stated upper and lower values above.

In the multi-layered light emitting film, an amount of the p-type organic semiconductor polymer may be, based on a total weight of the multi-layered light emitting film, greater than or equal to about 0.1 wt %, greater than or equal to about 0.5 wt %, greater than or equal to about 1 wt %, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, or greater than or equal to about 10 wt %. In the multi-layered light emitting film, an amount of the p-type organic semiconductor polymer may be, based on a total weight of the multi-layered light emitting film, less than or equal to about 30 wt %, less than or equal to about 25 wt %, less than or equal to about 20 wt %, less than or equal to about 15 wt %, less than or equal to about 10 wt %, or less than or equal to about 5 wt %. An amount of the p-type organic semiconductor polymer may be in a range provided by the stated upper and lower values above.

In the first layer, an amount of the p-type organic semiconductor polymer may be, based on a total weight of the first layer, greater than or equal to about 1 wt %, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 11 wt %, greater than or equal to about 12 wt %, greater than or equal to about 13 wt %, greater than or equal to about 14 wt %, greater than or equal to about 15 wt %, greater than or equal to about 16 wt %, greater than or equal to about 17 wt %, greater than or equal to about 18 wt %, greater than or equal to about 19 wt %, or greater than or equal to about 20 wt %. In the first layer, an amount of the p-type organic semiconductor polymer may be, based on a total weight of the first layer, less than or equal to about 40 wt %, less than or equal to about 35 wt %, less than or equal to about 30 wt %, less than or equal to about 25 wt %, or less than or equal to about 20 wt %. An amount of the p-type organic semiconductor polymer may be in a range provided by the stated upper and lower values above.

In an embodiment, the second layer of the multilayer light emitting film includes a plurality of second semiconductor nanoparticles, for example, the plurality of second particles are adjacent to (in contact with, e.g., being spaced by native ligands) the other. The second layer may not include the p-type organic semiconductor polymer described above. In the second layer, a second semiconductor nanoparticle may include an organic ligand and optionally a halogen, the organic ligand, and if present the halogen, each coordinated on a surface of the nanoparticle. Details of the organic ligand and halogen are as described herein.

In an embodiment, the second semiconductor nanoparticles in the second layer may be disposed adjacent to each other at intervals provided by, for example, an organic ligand or halogen, and at least a portion of the first semiconductor nanoparticles in the first layer may be surrounded by a p-type organic semiconductor polymer having a relatively bulky group in a repeating unit of the polymer.

In an embodiment, the plurality of the second semiconductor nanoparticles in the second layer may be more densely disposed than the plurality of the first semiconductor nanoparticles in the first layer, and thus the population density of the plurality of first semiconductor nanoparticles in the first layer may be less than the population density of the plurality of second semiconductor nanoparticles in the second layer.

In an embodiment, the population density may be determined with using an electron microscopy analysis of a multilayer light emitting film (e.g., a scanning or transmission electron microscopy with respect to a front face or cross-sectional face of the light emitting film/layer), for example, by the number of the semiconductor particles per predetermined area or unit area. In one embodiment, the population density may be related to an interparticle distance between the semiconductor nanoparticles. An average distance between particles can be determined by electron microscopy. Accordingly, a greater average distance between the semiconductor nanoparticles may result in or relates to a smaller population density thereof.

In an embodiment, an average distance between the first semiconductor nanoparticles in the first layer (i.e., an average inter-particle distance in the first layer) may be greater than or equal to about 1 nm, greater than or equal to about 2.5 nm, greater than or equal to about 5 nm, greater than or equal to about 7.5 nm, greater than or equal to about 9 nm, greater than or equal to about 10 nm, greater than or equal to about 10.5 nm, greater than or equal to about 11 nm, greater than or equal to about 11.5 nm, greater than or equal to about 12 nm, greater than or equal to about 12.5 nm, greater than or equal to about 13 nm, or greater than or equal to about 13.3 nm. The average distance between the first semiconductor nanoparticles in the first layer may be less than or equal to about 25 nm, less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 9 nm, or less than or equal to about 8 nm. An average distance between the first semiconductor nanoparticles in the first layer may be in a range provided by the stated upper and lower values above.

An average distance between the second semiconductor nanoparticles in the second layer (i.e., an average inter-particle distance in the first layer) may be greater than or equal to about 1 nm, greater than or equal to about 2.5 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 11.5 nm, or greater than or equal to about 12 nm. The average distance between the second semiconductor nanoparticles in the second layer may be less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 9 nm, less than or equal to about 8 nm, less than or equal to about 7 nm, less than or equal to about 6 nm, less than or equal to about 5 nm, or less than or equal to about 4 nm. An average distance between the second semiconductor nanoparticles in the second layer may be in a range provided by the stated upper and lower values above.

The average distance between particles in the first layer may be greater than the average distance between particles in the second layer. A difference between the average interparticle distance in the first layer and the average interparticle distance in the second layer may be from about 0.1 nm to about 3 nm, from about 0.2 nm to about 2.5 nm, from about 0.3 nm to about 2 nm, from about 0.35 nm to about 1.8 nm, from about 0.4 nm to about 1.5 nm, from about 0.45 nm to about 1.45 nm, from about 0.5 nm to about 1.25 nm, from about 0.6 nm to about 1.2 nm, from about 0.65 nm to about 1 nm, from about 0.7 nm to about 0.9 nm, from about 0.8 nm to about 0.85 nm, or a combination thereof.

In one embodiment, the second layer 13b may be disposed closer (e.g., proximate) to the electron auxiliary (e.g., electron transport) layer 14 than the first layer 13a, and in this case, the first layer may exhibit a higher hole transport property than the second layer, and/or the second layer may exhibit a higher electron transport property than the first layer. Without wishing to be bound by any theory, as the first semiconductor nanoparticles may be surrounded by the p-type organic semiconductor polymer in the first layer, the first layer may exhibit an increased level of hole transportation compared to the second layer where the second semiconductor nanoparticles are placed adjacent to each other (e.g., the second semiconductor nanoparticles being spaced by native ligands and capable of being dispersed by alkane solvents), whereby the p-n junction may be formed in the multi-layered light emitting film.

In an embodiment, the second layer 13b may be disposed further away from the electron transport layer 14 than the first layer 13a, and in this case, the second layer may exhibit higher hole transport properties than the first layer. In an embodiment, the second layer may be formed by the spin-dry process with using a metal halide alcohol solution on the film formed after the film is formed.

In the multi-layer light emitting film of an embodiment, the second layer may not include an n-type monomolecular organic semiconductor.

The n-type small molecule organic semiconductor may include 1,3,5-tri(diphenylphosphoryl-phen-3-yl) benzene (TP3PO), 2,4,6-Tris[3-(diphenylphosphinyl)phenyl]-1,3,5-triazine (POT2T), diphenylbis(4-(pyridine-3-yl)phenyl)silane(DPPS), 3-(4-biphenyl)-4-phenyl-5-tert-butylphenyl-1,2,4-triazole (TAZ), 4-(naphthalene-1-yl)-3,5-diphenyl-4H-1,2,4-triazole (NTAZ), 1,3,5-tris (1-phenyl-1H benzimidazole-2-yl) benzene (TPBi), 4,7-diphenyl-1,10-phenanthroline (Bphen), 1,3-bis[2-(2,2′-bipyridine-6-yl)-1,3,4-oxadiazo-5-il]benzene (Bpy-OXD), 2-(4-biphenyl)-5-(4-terbutylphenyl)-1,3,4-oxadiazole (PBD), basocuproin (BCP), 4,4′-bis(carbazole-9-yl)-2,2′-dimethylbiphenyl(CDBP), tris[3-(3-pyridyl)-mesityl] borane (3TPYMB), or a combination thereof.

In the multi-layered light emitting film of an embodiment, the second layer may not include a phenyl phosphoryl benzene compound, a diphenyl phosphinylphenyl triazine compound, or a combination thereof.

A thickness of the second layer may be selected taking into consideration the second semiconductor nanoparticle, a desired thickness of the light emitting film or layer, and/or desired electrical/optical properties of the film or layer. A thickness of the second layer may include one or more, for example, two or more, three or more, or four or more and 20 or less, 10 or less, 9 or less, 8 or less, 7 or less, or 6 or less monolayers of second semiconductor nanoparticles. The second layer may have a thickness of greater than or equal to about 5 nm, for example, greater than or equal to about 10 nm, greater than or equal to about 15 nm, or greater than or equal to about 20 nm. The second layer may have a thickness of less than or equal to about 80 nm, less than or equal to about 65 nm, less than or equal to about 60 nm, less than or equal to about 50 nm, less than or equal to about 45 nm, less than or equal to about 40 nm, less than or equal to about 35 nm, less than or equal to about 30 nm, less than or equal to about 25 nm, or less than or equal to about 20 nm. The second layer may have a thickness in a range provided by the stated upper and lower values above.

In an embodiment, a thickness of the multi-layered light emitting film may be greater than or equal to about 10 nm, greater than or equal to about 15 nm, greater than or equal to about 20 nm, greater than or equal to about 25 nm, greater than or equal to about 27 nm, or greater than or equal to about 30 nm. The thickness of the multi-layered light emitting film may be less than or equal to about 200 nm, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The thickness of the multi-layered light emitting film may be from about 10 nm to about 150 nm, from about 20 nm to about 100 nm, from about 30 nm to about 50 nm. The thickness of the multi-layered light emitting film may be in a range provided by the stated upper and lower values above.

In an embodiment, the first layer, the second layer, or the multi-layered light emitting film may exhibit an amount of an element (e.g., carbon, halogen, oxygen, or the like) that changes in a thickness direction. In the multi-layered light emitting film according to an embodiment, the halogen amount may increase in a direction toward the electron auxiliary layer. In the multi-layered light emitting film according to an embodiment, the carbon amount may decrease in a direction toward the electron auxiliary layer. In the multi-layered light emitting film according to an embodiment, the carbon amount may increase in a direction toward the electron auxiliary layer. In the multi-layered light emitting film according to an embodiment, the oxygen or nitrogen amount may decrease in a direction toward the electron auxiliary layer. In the multi-layered light emitting film according to an embodiment, the oxygen or nitrogen amount may increase in a direction toward the electron auxiliary layer. In the multi-layered light emitting film according to an embodiment, the halogen amount may decrease in a direction toward the electron auxiliary layer. In the (multilayer) light emitting layer according to an embodiment, the organic ligand amount may increase in a direction toward the electron auxiliary layer.

In an embodiment, the multi-layered light emitting film (or independently the first layer or the second layer) may have a residual thickness percentage of greater than or equal to about 10% (or greater than or equal to about 20%, greater than or equal to about 50%, greater than or equal to about 70%, greater than or equal to about 80%, greater than or equal to about 90%, or greater than or equal to about 95%) and less than or equal to 100% (or less than or equal to about 99%, less than or equal to about 95%) with respect to a C5-18 aliphatic hydrocarbon solvent, the residual thickness percentage being defined by the following equation:

residual thickness percentage=[B/A]×100

A: initial thickness of the light emitting film or layer

B: a thickness of the light emitting film or layer after being in contact with a given solvent for greater than or equal to 5 to less than or equal to 120 seconds (or from 10 seconds to 60 seconds).

The residual thickness percentage may be greater than or equal to about 15%, greater than or equal to about 25%, greater than or equal to about 35%, greater than or equal to about 45%, greater than or equal to about 55%, greater than or equal to about 65%, greater than or equal to about 75%, or greater than or equal to about 80%. The residual thickness percentage may be less than or equal to about 100%, less than or equal to about 99.5%, less than or equal to about 99%, less than or equal to about 98%, less than or equal to about 97%, less than or equal to about 96%, less than or equal to about 95%, less than or equal to about 94%, less than or equal to about 93%, less than or equal to about 92%, less than or equal to about 91%, less than or equal to about 90%, less than or equal to about 80%, less than or equal to about 70%, less than or equal to about 60%, less than or equal to about 50%, less than or equal to about 40%, less than or equal to about 30%, or less than or equal to about 20%. The residual thickness percentage may be in a range provided by the stated upper and lower values above.

In an embodiment, the electroluminescent device may include an electron auxiliary layer disposed between the multi-layered light emitting film and the second electrode. The electron auxiliary layer includes an electron transport layer. The electron transport layer includes zinc oxide nanoparticles and an organic liquid crystal compound. The electron transport layer may be present between an electrode (e.g., a second electrode or a second electrode) and the multi-layered light emitting film. The electron transport layer may be disposed on (e.g., directly on) the multi-layered light emitting film (e.g., the first layer or the second layer). The electron transport layer may be adjacent to the multi-layered light emitting film (e.g., the first layer or the second layer).

The zinc oxide nanoparticle may have a size or an average size (hereinafter, simply referred to as “size”) of greater than or equal to about 0.5 nm. The size of the zinc oxide nanoparticle may be less than or equal to about 50 nm. The size of the zinc oxide nanoparticles may be greater than or equal to about 1 nm, greater than or equal to about 2 nm, greater than or equal to about 2.5 nm, greater than or equal to about 3 nm, or greater than or equal to about 3.5 nm and less than or equal to about 20 nm, less than or equal to about 15 nm, less than or equal to about 10 nm, less than or equal to about 9 nm, less than or equal to about 8 nm, less than or equal to about 7 nm, less than or equal to about 6 nm, less than or equal to about 5 nm, or less than or equal to about 4.5 nm. The zinc oxide nanoparticle may have a size in a range provided by the stated upper and lower values above.

The term “zinc oxide nanoparticle” is used to define a nanoparticle that includes zinc and oxygen, and includes a nanoparticle that includes zinc, oxygen, and at least one or more of the following metals (elements).

In an embodiment, the zinc oxide nanoparticle may include a Group IIA metal and zirconium (Zr), tungsten (W), lithium (Li), titanium (Ti), yttrium (Y), aluminum (Al), gallium (Ga), indium (In), tin (Sn), cobalt (Co), vanadium (V), or a combination thereof. The Group IIA metal may include magnesium, calcium, barium, strontium, or a combination thereof. The zinc oxide nanoparticle may include the Group IIA metal (e.g., magnesium) and optionally an additional metal. The additional metal may include zirconium (Zr), tungsten (W), lithium (Li), titanium (Ti), yttrium (Y), aluminum (Al), gallium (Ga), indium (In), tin (Sn), cobalt (Co), vanadium (V), or a combination thereof.

In an embodiment, the zinc oxide nanoparticle may include Zn₁₋ₓM¹ₓO (where M¹ is a Group IIA metal and optionally, Zr, W, Li, Ti, Y, Al, gallium, indium, tin (Sn), cobalt (Co), vanadium (V), or a combination thereof, and 0≤x≤0.5). In the chemical formula Zn₁₋ₓM¹ₓO, x may be greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. In the chemical formula Zn₁₋ₓM¹ₓO, x may be less than or equal to about 0.47, less than or equal to about 0.45, less than or equal to about 0.43, less than or equal to about 0.4, less than or equal to about 0.37, less than or equal to about 0.35, or less than or equal to about 0.3.

The zinc oxide nanoparticle may further include magnesium. M1 may be magnesium. The zinc oxide nanoparticle may include Zn₁₋ₓM¹ₓO (x is greater than 0 and less than or equal to about 0.5, and x is as described herein). The x may be greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. The x may be less than or equal to about 0.47, less than or equal to about 0.45, less than or equal to about 0.43, less than or equal to about 0.4, less than or equal to about 0.37, less than or equal to about 0.35, or less than or equal to about 0.3.

In an embodiment, the zinc oxide nanoparticle may include a zinc magnesium oxide. In an embodiment, the zinc oxide nanoparticle may further include zirconium (Zr), tungsten (W), lithium (Li), titanium (Ti), yttrium (Y), aluminum (Al), gallium (Ga), indium (In), tin (Sn), cobalt (Co), vanadium (V), or a combination thereof. The zinc oxide nanoparticle may further include an alkali metal.

The alkali metal may include cesium, potassium, rubidium, or a combination thereof.

In an embodiment, the zinc oxide nanoparticle may be prepared by an appropriate method and is not particularly limited. In an embodiment, the zinc oxide nanoparticle may be obtained as follows: a zinc compound (e.g., an organic zinc compound such as zinc acetate dihydrate) and optionally an additional metal compound (e.g., an alkali metal compound, an alkaline earth metal compound, and/or a compound of a transition metal or the additional metal described herein) are placed in a desired mole ratio in a reactor, e.g., added in a desired mole ratio to a reactor, including an organic solvent (e.g., dimethylsulfoxide) and heated to a predetermined temperature (e.g., about 40° C. to about 120° C., or about 60° C. to about 100° C.) in air. A solution of a precipitation accelerator (e.g., an ethanol solution of tetramethylammonium hydroxide pentahydrate) may be added dropwise to the reactor at a predetermined rate and stirred. The prepared zinc oxide nanoparticle may be separated from the reaction solution by centrifugation.

The alkaline earth metal compound may include an alkaline earth metal organic compound such as a magnesium acetate hydrate, a calcium acetate hydrate, a barium acetate hydrate, or the like. The alkali metal compound may include an alkali metal carbonate compound such as cesium carbonate, lithium carbonate, rubidium carbonate, or the like.

A thickness of the electron transport layer may be greater than or equal to about 3 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 21 nm, greater than or equal to about 22 nm, greater than or equal to about 23 nm, greater than or equal to about 24 nm, greater than or equal to about 25 nm, greater than or equal to about 26 nm, greater than or equal to about 27 nm, greater than or equal to about 28 nm, greater than or equal to about 29 nm, greater than or equal to about 30 nm, greater than or equal to about 31 nm, greater than or equal to about 32 nm, greater than or equal to about 33 nm, greater than or equal to about 34 nm, or greater than or equal to about 35 nm. A thickness of the electron transport layer may be less than or equal to about 90 nm, less than or equal to about 80 nm, less than or equal to about 70 nm, less than or equal to about 60 nm, less than or equal to about 50 nm, less than or equal to about 45 nm, less than or equal to about 40 nm, or less than or equal to about 35 nm. The thickness of the electron transport layer may be in a range provided by the stated upper and lower values above.

In an embodiment, the electron auxiliary layer may further include an electron injection layer, a hole blocking layer, or a combination thereof. The thickness of the electron injection layer, the hole blocking layer, or a combination thereof is not particularly limited and may be appropriately selected. A thickness of the electron injection layer, the hole blocking layer, or a combination thereof may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

In an embodiment, a material for the electron injection layer, a material for the hole blocking layer, or a combination thereof may be appropriately selected and is not particularly limited.

In an embodiment, a material of the electron injection layer, hole blocking layer, or a combination thereof may include 1,4,5,8-naphthalene-tetracarboxylic dianhydride (NTCDA), bathocuproine(bathocuproine (BCP), tris[3-(3-pyridyl)-mesityl]borane (3TPYMB), LiF, Alq₃, Gaq₃, Inq₃, Znq₂, Zn(BTZ)₂, BeBq₂, ET204 (8-(4-(4,6-di(naphthalen-2-yl)-1,3,5-triazin-2-yl)phenyl)quinolone), 8-hydroxyquinolinato lithium (Liq), 2,2′,2″-(1,3,5-Benzinetriyl)-tris(1-phenyl-1-H-benzimidazole) (TPBi), an n-type metal oxide (e.g., zinc oxide, HfO₂, etc.), 8-(4-(4,6-di(naphthalen-2-yl)-1,3,5-triazin-2-yl)phenyl)quinolone:8-hydroxyquinolinato lithium (ET204:Liq), or a combination thereof, but is not limited thereto.

The light emitting device according to an embodiment may further include a hole auxiliary layer. The hole auxiliary layer is disposed between the first electrode and the light emitting layer. The hole auxiliary layer may include a hole injection layer, a hole transport layer, an electron (or hole) blocking layer, or a combination thereof. The hole auxiliary layer may be a layer of a single component or a multilayer structure in which adjacent layers include different components.

The hole auxiliary layer may have a HOMO energy level that can be matched with the HOMO energy level of the light emitting layer to enhance mobility of holes transferred from the hole auxiliary layer to the light emitting layer. In an embodiment, the hole auxiliary layer may include a hole injection layer proximate to the first electrode and a hole transport layer proximate to the light emitting layer.

The material included in the hole auxiliary layer (e.g., a hole transport layer, a hole injection layer, or an electron blocking layer) is not particularly limited, and may include, for example, poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene) polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenyl]cyclohexane (TAPC), a p-type metal oxide (e.g., NiO, WO₃, MoO₃, etc.), a carbon-based material such as graphene oxide, or a combination thereof, but is not limited thereto.

In the hole auxiliary layer, the thickness of each layer may be appropriately selected. For example, the thickness of each layer may be greater than or equal to about 5 nm, greater than or equal to about 10 nm, greater than or equal to about nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm, but is not limited thereto.

A device according to an embodiment may have a normal structure. In an embodiment of FIG. 2 the device may include a first electrode 10 disposed on a transparent substrate 100, e.g., a metal oxide-based transparent electrode (e.g., an ITO electrode), and a second electrode 50 facing the first electrode 10 may include a conductive metal (e.g., having a relatively low work function, Mg, Al, etc.). The hole auxiliary layer 20 (e.g., a hole injection layer such as PEDOT:PSS, a p-type metal oxide, or a combination thereof; a hole transport layer such as TFB, polyvinylcarbazole (PVK), or a combination thereof; or a combination thereof) may be provided between the transparent electrode 10 and the light emitting layer 30. The hole injection layer may be disposed close to the transparent electrode and the hole transport layer may be disposed close to the light emitting layer. The electron auxiliary layer 40 such as an electron injection/transport layer may be disposed between the light emitting layer 30 and the second electrode 50.

A device according to an embodiment may have an inverted structure as depicted in FIG. 3. A second electrode 50 disposed on the transparent substrate 100 may include a metal oxide-based transparent electrode (e.g., ITO), and a first electrode 10 facing the second electrode 50 may include a metal (e.g., having a relatively high work function, Au, Ag, etc.). For example, an (optionally doped) n-type metal oxide (crystalline Zn metal oxide) or the like may be disposed as an electron auxiliary layer 40 (e.g., an electron transport layer) between the transparent electrode 50 and the light emitting layer 30. MoO₃ or other p-type metal oxide may be disposed as a hole auxiliary layer 20 (e.g., a hole transport layer including TFB, PVK, or a combination thereof; a hole injection layer including MoO₃ or other p-type metal oxide; or a combination thereof) between the metal first electrode 10 and the light emitting layer 30.

In an embodiment, a method of producing an electroluminescent device includes forming the light emitting layer on the first electrode; forming an electron transport layer on the light emitting layer; and forming a second electrode on the electron transport layer.

In an embodiment, the forming of the multilayer light emitting layer includes:
forming a film of a first composition including an organic solvent, a precursor of a p-type organic semiconductor polymer, and the first semiconductor nanoparticles and thermally treating (e.g., heating) the film at a temperature of greater than or equal to about 110° C., and less than or equal to about 180° C. to form the first layer; and
forming a film of a second composition including an organic solvent and the second semiconductor nanoparticles and removing the organic solvent from the film to form the second layer.

The forming of the first layer may not include or involve a UV light irradiation. The UV light irradiation may be conducted by using of a UV light having a wavelength of less than or equal to about 400 nm.

The heat treatment may be carried out at a temperature of greater than or equal to about 115° C., greater than or equal to about 120° C., greater than or equal to about 125° C., greater than or equal to about 130° C., greater than or equal to about 135° C., greater than or equal to about 140° C., greater than or equal to about 145° C., greater than or equal to about 150° C., or greater than or equal to about 155° C. The thermal treatment may be carried out at a temperature of less than about 180° C., less than or equal to about 175° C., less than or equal to about 170° C., less than or equal to about 165° C., less than or equal to about 160° C., or less than or equal to about 155° C. The thermal treatment may be carried out in an inert gas atmosphere.

The first composition may include or may not further include an active component for increasing the reaction of the precursor of the p-type organic semiconductor polymer. The active ingredient may include various acid generator (AG), a radical generator (e.g., AlBN), or a combination thereof. The active component may provide acid or radicals by light or heat. The acid generator may include an ionic compound or a nonionic compound. The acid generator may include a diazo compound, an onium compound, a sulfonic acid compound, an iodonium compound, or a combination thereof, but is not limited thereto.

Details of the first electrode, the second electrode, the electron transport layer, the first semiconductor nanoparticles, the second semiconductor nanoparticles, and the p-type organic semiconductor polymer are as described above.

In one embodiment, the organic solvent may include chloroform, dichloromethane, a (substituted or unsubstituted) aliphatic hydrocarbon organic solvent, a (substituted or unsubstituted) aromatic hydrocarbon organic solvent (e.g., toluene, xylene, dimethylbenzene, bromobenzene, etc.), an acetate solvent, or a combination thereof. The (substituted or unsubstituted) aliphatic hydrocarbon organic solvent may include substituted or unsubstituted linear or branched C3-30 alkane (e.g., pentane, hexane, heptane, octane, nonan, decane, undecane, dodecane, substituted or unsubstituted linear or branched C3-30 alkane, or a combination thereof.

The formation of the first or second layer may be carried out in an appropriate way (e.g., by spin coating, inkjet printing, etc.), by applying or depositing a first composition (or a second composition) on an electrode, a charge auxiliary layer (e.g., a hole auxiliary layer), or a second layer (or a first layer).

In an embodiment, a first layer may be formed on an electrode or a charge auxiliary layer, and a second layer may be formed on the first layer. In an embodiment, a second layer may be formed on an electrode or a charge auxiliary layer, a spin dry treatment using a metal chloride solution may be performed on the second layer, and then the first layer may be formed on the second layer.

The metal chloride solution may include a zinc chloride and a C1 to 010 alcohol solvent (e.g., ethanol, methanol, etc.). A spin dry treatment can include a drop-casting and spinning the metal chloride solution on the formed layer to contact the metal chloride solution with the layer. The spin dry treatment may include washing a treated film with a polar solvent and optionally drying the washed film.

The drying may include a heat treatment conducted at a temperature of from about 60° C. to about 150° C., from about 80° C. to about 120° C., or a combination thereof.

In an embodiment, the formation of the light emitting layer may be performed by an inkjet method. In an embodiment, the formation of the light emitting film may include producing an ink composition (e.g., a first composition or a second composition) that is configured to form a pattern in an inkjet method, providing a substrate (e.g., patterned by a partition wall, bank, and/or black matrix), depositing the ink composition on the substrate (e.g., in the pixel area) and if necessary, carrying out a heat treatment (e.g., for a formation of a first layer).

In an embodiment, an electrode and a hole auxiliary layer may be formed by an appropriate manner (e.g., by deposition or coating) on a substrate. The electrode and the hole auxiliary layer may be patterned. The formation of the electron auxiliary layer (e.g., the electron transport layer) may include forming a film including the zinc oxide nanoparticles on the multilayered light emitting film. The formation of the film may include preparing a composition (e.g., dispersion) including the zinc oxide nanoparticles and applying it on the multi-layered light emitting film. The composition or the dispersion may further include an organic solvent. The method may include heat-treating the formed film.

The details of the zinc oxide nanoparticles are as described above. Preparation of the composition may include adding the zinc metal oxide nanoparticles into an organic solvent. The organic solvent can be a C1 to 010 alcohol solvent (e.g., ethanol, methanol, propanol, butanol, pentanol, etc.), or a combination thereof.

In an embodiment, for example, in order to remove an organic solvent or the like, the coated film may be heat-treated at a predetermined temperature, for example, at a temperature of greater than or equal to about 50° C. and less than or equal to about 250°, greater than or equal to about 80° C. and less than or equal to about 120° C. The heat treatment may be carried out, for example, in an inert gas atmosphere such as nitrogen or argon or in an atmosphere. The thermal treatment temperature may be less than 120° C., 115° C. or less, 110° C. or less, 105° C. or less, 100° C. or less, 95° C. or less, 90° C. or less, or 85° C. or less. The heat treatment temperature may be 40° C. or more, 50° C. or more, 60° C. or more, 65° C., 70° C. or more, or 75° C. or more.

The electroluminescent device of an embodiment may exhibit an improved level of electroluminescent properties and may show an increased lifespan.

The electroluminescent device of an embodiment may exhibit a maximum external quantum efficiency (EQE) of greater than or equal to about 5%, greater than or equal to about 5.5%, greater than or equal to about 6%, greater than or equal to about 6.5%, greater than or equal to about 7%, greater than or equal to about 7.5%, greater than or equal to about 7.7%, greater than or equal to about 8%, greater than or equal to about 8.5%, greater than or equal to about 9%, greater than or equal to about 9.5%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The electroluminescent device may exhibit the maximum external quantum efficiency (EQE) of less than or equal to about 60%, less than or equal to about 50%, less than or equal to about 40%, less than or equal to about 30%, or less than or equal to about 20%.

The electroluminescent device may exhibit maximum luminance of greater than or equal to about 60,000 candelas per square meter (cd/m²), greater than or equal to about 75,000 cd/m², greater than or equal to about 77,000 cd/m², greater than or equal to about 78,000 cd/m², greater than or equal to about 79,000 cd/m², greater than or equal to about 80,000 cd/m², greater than or equal to about 85,000 cd/m², greater than or equal to about 90,000 cd/m², greater than or equal to about 95,000 cd/m², greater than or equal to about 100,000 cd/m², greater than or equal to about 120,000 cd/m², greater than or equal to about 150,000 cd/m², greater than or equal to about 200,000 cd/m², greater than or equal to about 250,000 cd/m², or greater than or equal to about 300,000 cd/m². The electroluminescent device may exhibit a maximum luminance of less than or equal to about 5,000,000 cd/m², less than or equal to about 1,000,000 cd/m², less than or equal to about 900,000 cd/m², or less than or equal to about 500,000 cd/m². The electroluminescent device may exhibit a maximum luminance in a range provided by the stated upper and lower values above.

The electroluminescent device of one embodiment may exhibit, for example, when being driven at a predetermined initial luminance (e.g., about 650 nit (cd/m²)), a T50 of greater than or equal to about 20 hours, for example, greater than or equal to about 25 hours, greater than or equal to about 30 hours, greater than or equal to about 40 hours, greater than or equal to about 50 hours, greater than or equal to about 60 hours, greater than or equal to about 65 hours, greater than or equal to about 70 hours, greater than or equal to about 80 hours, greater than or equal to about 90 hours, greater than or equal to about 100 hours, greater than or equal to about 110 hours, greater than or equal to about 115 hours, greater than or equal to about 120 hours, greater than or equal to about 125 hours, greater than or equal to about 130 hours, greater than or equal to about 140 hours, or greater than or equal to about 145 hours. For example, the T50 may range from about 25 hours to about 1,000 hours, about 26 hours to about 500 hours, about 26.5 hours to about 300 hours, or a combination thereof.

The electroluminescent device may exhibit, for example, when being driven at a predetermined initial luminance (e.g., about 650 nit), a T90 of greater than or equal to about 15 hours, greater than or equal to about 16 hours, greater than or equal to about 17 hours, greater than or equal to about 20 hours, greater than or equal to about 23 hours, greater than or equal to about 25 hours, or greater than or equal to about 30 hours. For example, the electroluminescent device may exhibit a T90 of about 7 hours to about 1,000 hours, about 8 hours to about 800 hours, about 10 hours to about 500 hours, about 50 hours to about 300 hours, about 80 hours to about 250 hours, about 90 hours to about 120 hours, or a combination thereof (when driven at a predetermined luminance, for example, 650 nit).

In an embodiment, the electroluminescent device may exhibit a voltage increase of less than or equal to about 0.6 volts, or less than or equal to about 0.5 volts as operated at an initial luminance of about 650 nit for a predetermined hours (e.g., about 80 hours). The voltage increase may be a difference between an initial voltage and a voltage operated for the predetermined hours.

An embodiment relates to a display device including the aforementioned electroluminescent device.

The display device may include a first pixel and a second pixel configured to emit light of a color differing from that of the first pixel. In the first pixel, the second pixel, or a combination thereof, the electroluminescent device according to an embodiment (e.g., with the electron transport layer described herein) may be disposed. In an embodiment, the display device may further include a blue pixel, a red pixel, a green pixel, or a combination thereof. In the display device, the red pixel may include a red light emitting layer including a plurality of red light emitting semiconductor nanoparticles, the green pixel may include a green light emitting layer including a plurality of green light emitting semiconductor nanoparticles, and the blue pixel may include a blue light emitting layer including a plurality of blue light emitting semiconductor nanoparticles.

The display device may include a portable terminal device, a monitor, a laptop, a television, an electric sign board, a camera, or an electronic component.

Hereinafter, specific examples are illustrated. However, these examples are exemplary, and the present disclosure is not limited thereto.

### EXAMPLES

### Analysis Methods

### 1. Electroluminescence Spectroscopic Analysis

A current is measured with a Keithley 2635B source meter as a voltage is applied. A CS2000 spectrometer is used to measure electroluminescence (EL) light-emitting luminance.

### 2. Life-Span Characteristic

(1) T50: represents a time in hours (hr) for luminance to reach 50% of initial luminance when driven with a predetermined luminance of 650 nit (candelas per square meter),

T90: represents a time in hours (hr) for luminance to reach 90% of initial luminance when driven with a predetermined luminance of 650 nit (candelas per square meter).

### 3. UV-Vis Absorption Spectroscopy Analysis

A UV-Vis absorption spectroscopy is carried out by using an Agilent Cary5000 spectrophotometer and a UV-visible absorption spectrum is obtained. Bandgap energy of a given material can be obtained from the obtained UV-Vis absorption spectrum.

### 4. AC3 Analysis and HOMO Measurement

The measurements are made using a surface analyzer (Model AC-3, photoelectron spectrophotometer in Air) of Riken Keiki Co. Ltd in air.

The following synthesis is performed under an inert gas atmosphere (under nitrogen) unless otherwise specified. A precursor amount is a molar amount, unless otherwise specified.

### Synthesis Example 1-1

Selenium (Se), sulfur (S) and tellurium (Te) are dispersed in trioctylphosphine (TOP) to prepare a Se/TOP stock solution, a S/TOP stock solution, and a Te/TOP stock solution, respectively. To a reactor containing trioctylamine, 0.125 millimoles (mmol) of zinc acetate with oleic acid are added, and then the mixture is heated to 120° C. under vacuum. After 1 hour, an atmosphere of nitrogen is introduced into the reactor.

The reactor is heated to 300° C. and the prepared Se/TOP stock solution and Te/TOP stock solution in a mole ratio Te:Se of 1:20 are rapidly injected into the heated reactor. Upon completion of the reaction, the reaction mixture is rapidly cooled to room temperature, and then acetone is added to facilitate formation of a precipitate. The precipitate is separated by centrifugation and dispersed in toluene to obtain ZnSeTe core particles in toluene.

To a reaction flask containing trioctylamine, 1.8 mmol of zinc acetate and oleic acid are added, and the mixture is vacuum-treated, e.g., subjected to vacuum conditions at 120° C. for 10 minutes. An atmosphere of nitrogen is introduced into the flask and the flask heated to 180° C. The above prepared ZnTeSe core particles are added to the flask followed by the injection of the prepared Se/TOP and S/TOP stock solutions. The reaction temperature is set at about 280° C. Upon completion of the reaction, the reactor is cooled, ethanol is added, and the nanocrystals are separated with a centrifuge and dispersed in toluene, to prepare blue light-emitting semiconductor nanoparticles.

By a photoluminescence analysis, it is confirmed that the blue light-emitting semiconductor nanoparticles have a maximum luminescent peak wavelength of 455 nanometers (nm).

### Synthesis Example 1-2

The semiconductor nanoparticles (optical density: 0.25 at 420 nm, 6 milliliters (mL)) synthesized in Synthesis Example 1-1 are precipitated in ethanol and then, centrifuged, and re-dispersed in cyclohexane, to prepare a cyclohexane dispersion. An amount of 0.022 millimoles (mmol) of zinc chloride dissolved in ethanol is added to the cyclohexane dispersion and stirred at 80° C. for 30 minutes. The treated semiconductor nanoparticles are separated through centrifugation and dispersed in octane, to prepare an octane dispersion.

### Synthesis Example 2: Synthesis of ZnMgO Nanoparticles

Zinc acetate dihydrate and magnesium acetate tetrahydrate are added to a reactor containing dimethyl sulfoxide and heated to 60° C. under air. An ethanol solution of tetramethylammonium hydroxide pentahydrate is then added to the reactor. After 1 hour of stirring, a precipitate forms that is then separated with a centrifuge and dispersed in ethanol, obtaining Zn₁₋ₓM¹ₓO nanoparticles. (x=0.15)

A transmission electron microscope analysis of the nanoparticles confirms that the particles have an average size of about 3 nm.

### Experimental Example 1

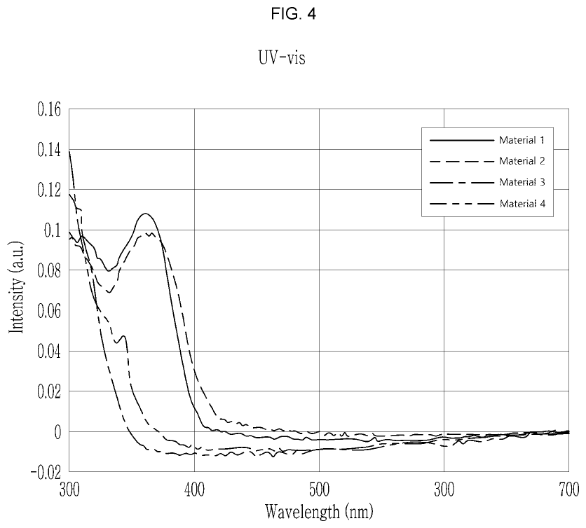

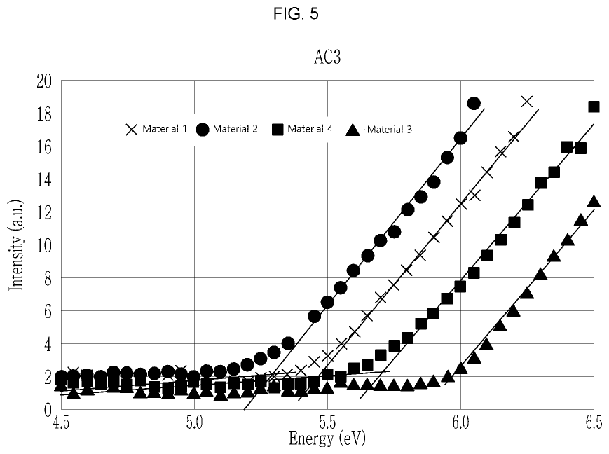

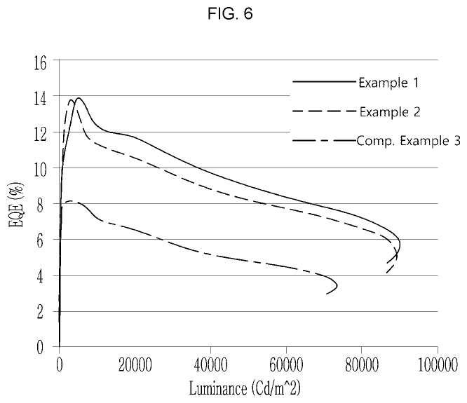

With respect to four materials, a UV-Vis absorption spectroscopy analysis and a AC3 analysis are carried out to determine bandgap energy and the results are shown in FIG. 4 and FIG. 5.

Material 1: N4,N4′-Bis(4-(6-((3-ethyloxetan-3-yl)methoxy)hexyl)phenyl)-N4,N4′-di phenylbiphenyl-4,4′-diamine,

Material 2: N4,N4′-Bis(4-(6-((3-ethyloxetan-3-yl)methoxy)hexyloxy)phenyl)-N4,N4′-bis(4-methoxyphenyl)biphenyl-4,4′-diamine,

Material 3: N,N′-(4,4′-(Cyclohexane-1,1-diyl)bis (4,1-phenylene))bis(N-(4-(6-(2-ethyloxetan-2-yloxy)hexyl)phenyl)-3,4,5-trifluoroaniline),

Material 4: 3,5-Di-9H-carbazol-9-yl-N, N-bis[4-[[6-[(3-ethyl-3-oxetanyl) methoxy]hexyl]oxy]phenyl]benzenamine

From the results of FIG. 4 and FIG. 5, HOMO and LUMO of Materials 1 to 4 are calculated and the results are shown in Table 1.

TABLE 1

Energy Level (eV)

| | | |
|---|---|---|
| Material 1 | HOMO | 5.46 |
| | LUMO | 2.41 |
| Material 2 | HOMO | 5.25 |
| | LUMO | 2.25 |
| Material 3 | HOMO | 5.97 |
| | LUMO | 2.47 |
| Material 4 | HOMO | 5.69 |
| | LUMO | 2.31 |

From Table 1, it is confirmed that Materials 1 to 4 have various bandgap energies and HOMO/LUMO energies.

### Comparative Example 1

An electroluminescent device with a structure of indium tin oxide (ITO)/poly(3,4-ethylenedioxythiophene) polystyrene sulfonate (PEDOT:PSS) (30 nm)/poly(9,9-dioctyl-fluorene-co-N-(4)-butylphenyl)-diphenylamine) (TFB) (25 nm)/quantum dot (QD) light emitting film (20 nm)/electron transport layer (ETL) (20 nm)/AI (100 nm) is manufactured according to the following method:

The zinc magnesium oxide nanoparticles according to Synthesis Example 2 are dispersed in ethanol to prepare a ETL dispersion.

The semiconductor nanoparticle prepared in Synthesis Example 1-1 and Material 1 (manufactured by Lumtec, Cas No. 746634-00-4) are mixed in octane to prepare a light emitting film forming composition. In the light emitting film forming composition, an amount of Material 1 is about 10 wt %, based on a total weight of the semiconductor nanoparticle and Material 1.

After surface-treating a glass substrate deposited with ITO with ultraviolet (UV)-ozone for 15 minutes, a PEDOT:PSS solution (H.C. Starks, Inc.) is spin-coated thereon and heat-treated at 150° C. for 10 minutes under an air atmosphere and then, at 150° C. for 20 to 30 minutes under a N₂ atmosphere to form a 30 nm to about thick hole injection layer.

On the hole injection layer (HIL), a poly[(9,9-dioctylfluoren-2,7-diyl-co-(4,4′-(N-4-butylphenyl)diphenylamine] solution (TFB) (Sumitomo Corp.) is spin-coated and heat-treated at 180° C. for 30 minutes, forming a 25 nm to about thick hole transport layer (HTL).

On the hole transport layer (HTL), the light emitting film forming composition is spin-coated and heated at a temperature of about 140° C. to form a nm thick light emitting layer.

On the formed light emitting layer, the ETL dispersions is spin-coated and heat-treated at 80° C., forming an electron transport layer (thickness: 20 nm). On the prepared electron transport layer, aluminum (Al) is vacuum-deposited, e.g., deposited under vacuum, to be 100 nm thick, e.g., deposited to a thickness of 100 nm, forming a second electrode and manufacturing a light emitting device.

The electroluminescent properties and the lifespan of the electroluminescent device thus obtained are measured, and the results are shown in Table 2. The T90 and the T50 of the electroluminescent device are about 0.89 hours and about 7.9 hours, respectively.

### Comparative Example 2

An electroluminescent device is prepared in the same manner as in Comparative Example 1 except that UV irradiation, not the heat-treatment, is used to form the light emitting layer.

The measurement of the electroluminescent properties was carried out but the device failed to exhibit the luminescent properties.

### Example 1

An electroluminescent device with a structure of indium tin oxide (ITO)/poly(3,4-ethylenedioxythiophene) polystyrene sulfonate (PEDOT:PSS) (30 nm)/poly(9,9-dioctyl-fluorene-co-N-(4)-butylphenyl)-diphenylamine) (TFB) (25 nm)/multi-layered light emitting film (first layer 20 nm and second layer 20 nm)/electron transport layer (ETL) (20 nm)/AI (100 nm) is manufactured according to the following method:

The zinc magnesium oxide nanoparticles according to Synthesis Example 2 are dispersed in ethanol to prepare a ETL dispersion. The semiconductor nanoparticle prepared in Synthesis Example 1-1 and Material 1 (manufactured by Lumtec, Cas No. 746634-00-4) are mixed in octane to prepare a first composition of a first light emitting layer. In the first composition, an amount of Material 1 is about 15 wt %, based on a total weight of the semiconductor nanoparticle and Material 1. The semiconductor nanoparticle prepared in Synthesis Example 1-1 are dispersed in octane to prepare a second composition for a second light emitting layer.

After surface-treating a glass substrate deposited with ITO with ultraviolet (UV)-ozone for 15 minutes, a PEDOT:PSS solution (H.C. Starks, Inc.) is spin-coated thereon and heat-treated at 150° C. for 10 minutes under an air atmosphere and then, at 150° C. for 20 to 30 minutes under a N₂ atmosphere to form a 30 nm thick hole injection layer.

On the hole injection layer (HIL), a poly[(9,9-dioctylfluoren-2,7-diyl-co-(4,4′-(N-4-butylphenyl)diphenylamine] solution (TFB) (Sumitomo Corp.) is spin-coated and heat-treated at 180° C. for 30 minutes, forming a 25 nm thick hole transport layer (HTL).

On the hole transport layer (HTL), the first composition (including Synthesis Example 1-1 and Material 1) is spin-coated and heated at a temperature of about 150° C. for 30 minutes to form a 20 nm thick first light emitting layer. On the first light emitting layer, the second composition (including Synthesis Example 1-1) is spin-coated and heat-treated at 80° C. to form a second light emitting layer.

On the multi-layered light emitting film thus obtained, the ETL dispersions is spin-coated and heat-treated at 80° C., forming an electron transport layer (thickness: 20 nm). On the prepared electron transport layer, aluminum (Al) is vacuum-deposited, e.g., deposited under vacuum, to be 100 nm thick, e.g., deposited to a thickness of 100 nm, forming a second electrode and manufacturing a light emitting device. In the electroluminescent device, the second layer is disposed between the first layer and the electron transport layer.

The electroluminescent properties and the lifespan of the electroluminescent device are measured and the results are shown in Table 2. The T90 and the T50 of the electroluminescent device are about 18 hours and about 125 hours, respectively.

### Example 2

An electroluminescent device is prepared in the same manner as in Example 1 except for the following:

A zinc chloride ethanol solution for spin-dry treatment is prepared by dissolving zinc chloride in ethanol.

The second composition (including Synthesis Example 1-1) is spin-coated on the obtained hole transport layer to obtain a film, heated at 80° C. for 20 minutes under a nitrogen atmosphere, and then the zinc chloride ethanol solution is drop casted on the obtained film, maintained for 60 seconds, and spun again. In order to remove excess zinc chloride, a washing is conducted with ethanol by a spin coating and the obtained film is heated at 150° C. for 20 minutes to form a SPD-treated second layer having a thickness of 20 nm. A first composition (including Synthesis Example 1-1 and Material 1) is spin-coated on the SPD-treated second layer and heated at 150° C. for 30 minutes to form a first layer having a thickness of nm on the second layer. The first layer is disposed between the electron transport layer and the second layer

The electroluminescent properties and the lifespan of the electroluminescent device thus obtained are measured, and the results are shown in Table 2. The T90 and the T50 of the electroluminescent device are about 19 hours and about 160 hours, respectively.

### Comparative Example 3

An electroluminescent device is prepared in the same manner as in Example 1 except for the following:

A zinc chloride ethanol solution for spin-dry treatment is prepared by dissolving zinc chloride in ethanol.

The second composition is spin-coated on the obtained hole transport layer to obtain a film, heated at 80° C. for 20 minutes under a nitrogen atmosphere, and then the zinc chloride ethanol solution is drop casted on the obtained film, maintained for 60 seconds, and spun again. In order to remove excess zinc chloride, a washing is conducted with ethanol by a spin coating, and the obtained film is heated at 150° C. for 20 minutes to form a SPD-treated second layer having a thickness of 20 nm. A second composition is spin-coated on the SPD-treated second layer and heated at 150° C. for 30 minutes to form a second layer having a thickness of 20 nm on the SPD-treated second layer.

The electroluminescent properties and the lifespan of the electroluminescent device thus obtained are measured, and the results are shown in Table 2.

TABLE 2

| | Maximum EQE | Maximum luminance |
|---|---|---|
| | (%) | (cd/m²) |
| Example 1 | 13.9 | 89912 |
| Example 2 | 13.8 | 89284 |
| Comp. Example 1 | 8.1 | 39795 |
| Comp. Example 3 | 8.1 | 73600 |

The results of Table 1 confirm that the electroluminescent devices of Examples 1 to 2 exhibit improved electroluminescent properties in comparison with the electroluminescent devices of Comparative Examples.

### Experimental Example 2

The semiconductor nanoparticle prepared in Synthesis Example 1-1 and Material 1 (manufactured by Lumtec, Cas No. 746634-00-4) are mixed in octane to prepare a first composition of a first light emitting layer. In the first composition, an amount of Material 1 is about 15 wt %, based on a total weight of the semiconductor nanoparticle and Material 1.

The obtained first composition is disposed on the substrate and heat-treated at 80° C., 120° C., 140° C., and 160° C. for 30 minutes, respectively, to prepare the films. After the heat treatment, octane is brought into contact with each of the prepared thin films for 5 seconds, the residual thickness percentage for each of the films is measured, and the results are summarized in Table 3.

TABLE 3

| | 80° C. | 120° C. | 140° C. | 160° C. |
|---|---|---|---|---|
| residual thickness | 81% | 99% | 100% | 100% |
| percentage | | | | |

From the results of Table 3, it is confirmed that the residual thickness percentage with respect to octane can be significantly increased by the thermal treatment.

### Examples 4-1 to 4-3

An electroluminescent device is prepared in substantially the same manner as in Example 2 except for the following:

In the first composition, the amount of material 1 is 10% by weight based on the total weight of semiconductor nanoparticles and material 1, the thickness of the SPD-treated second layer is 20 nm, and the thickness of the first layer is 12 nm (Embodiment 4-1), 16 nm (Embodiment 4-2), and 20 nm (Embodiment 4-3), respectively.

The electroluminescent properties and the lifespan of the electroluminescent device thus obtained are measured, and the results are shown in Table 4.

### Comparative Example 4

An electroluminescent device is prepared in substantially the same manner as in Example 2 except for the following:

Instead of forming the first layer, the second composition is spin-coated on the SPD-treated second layer (20 nm) and heated at 80° C. for 20 minutes to form a second layer with a thickness of 20 nm.

The electroluminescent properties and the lifespan of the electroluminescent device thus obtained are measured, and the results are shown in Table 4.

TABLE 4

| | | Relative | |
|---|---|---|---|
| | | percentage of | |
| | | the maximum | T90 |
| | Light Emitting Film | EQE ^{note1} | (hours) |
| Comp. | SPD-treated second layer | 100% | 51.12 |
| Example 4 | (20 nm)/second layer (20 nm) | | |
| Example | SPD-treated second layer | 129% | 73.54 |
| 4-1 | (20 nm)/first layer (12 nm) | | |
| Example | SPD-treated second layer | 139% | 63.66 |
| 4-2 | (20 nm)/first layer (16 nm) | | |
| Example | SPD-treated second layer | 143% | 101.96 |
| 4-3 | (20 nm)/first layer (20 nm) | | |

note 1: Relative percentage to maximum EQE in comparison with the max EQE of Comparative Example 4

From the results of Table 4, it is confirmed that the device of Examples 4-1 to 4-3 including the multi-layered emission including the first layer and the second layer may exhibit an increased life with improved maximum EQE (external quantum efficiency) in comparison with the device of Comparative Example 4.

### Examples 5-1 to 5-4

An electroluminescent device is prepared in substantially the same manner as in Example 2 except for the following:

In the first composition, the amount of material 1 is 5% by weight (Example 5-1), 10% by weight (Example 5-2), 15% by weight (Example 5-3), and 20% by weight (Example 5-4), and the thickness of the SPD-treated second layer is 20 nm, and the thickness of the first layer is 20 nm. The first layer is disposed between the electron transport layer and the second layer.

### Comparative Example 5

An electroluminescent device is prepared in substantially the same manner as in Example 2 except for the following:

Instead of forming the first layer, the octane dispersion of the semiconductor nanoparticles prepared in Synthesis Example 1-2 is spin-coated as a second composition and heated at 80° C. for 20 minutes to form a second layer having a thickness of 20 nm.

The electroluminescent properties and the lifespan of the electroluminescent device thus obtained are measured, and the results are shown in Table 5.

TABLE 5

| | | Relative | | Amount |
|---|---|---|---|---|
| | | percentage of | | of |
| | | the maximum | T90 | Material |
| | Light emitting film | EQE ^{note1} | (hours) | 1 |
| Comp. | SPD-treated second layer | 100% | 39.78 | 0% |
| Example 5 | (20 nm)/second layer (20 nm) | | | |
| Example | SPD-treated second layer | 210% | 88.27 | 5 wt % |
| 5-1 | (20 nm)/first layer (20 nm) | | | |
| Example | SPD-treated second layer | 268% | 82.57 | 10 wt % |
| 5-2 | (20 nm)/first layer (20 nm) | | | |
| Example | SPD-treated second layer | 273% | 72.75 | 15 wt % |
| 5-3 | (20 nm)/first layer (20 nm) | | | |
| Example | SPD-treated second layer | 200% | 90.80 | 20 wt % |
| 5-4 | (20 nm)/first layer (20 nm) | | | |

^{note1}:
Relative percentage to maximum EQE in comparison with the max EQE of Comparative Example 5

From the results of Table 5, it is confirmed that the device of Examples 5-1 to 5-4 including the multi-layered emission including the first layer and the second layer may exhibit an increased life with improved maximum EQE (external quantum efficiency) in comparison with the device of Comparative Example 5.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. An electroluminescent device, comprising:
a first electrode;
a second electrode;
a multi-layered light emitting film disposed between the first electrode and the second electrode; and
an electron transport layer disposed between the multi-layered light emitting film and the second electrode,
wherein the multi-layered light emitting film is configured to emit a first light having a predetermined peak emission wavelength,
wherein the multi-layered light emitting film comprises a first layer and a second layer disposed on the first layer, the first layer comprising a plurality of first semiconductor nanoparticles surrounded by a p-type organic semiconductor polymer, and the second layer comprising a plurality of second semiconductor nanoparticles.

2. The electroluminescent device of claim 1, wherein
the predetermined peak emission wavelength is in a blue wavelength region, a green wavelength region, or a red wavelength region, and a full width at half maximum of an emission peak of the first light is greater than or equal to about nanometers and less than or equal to about 50 nanometers.

3. The electroluminescent device of claim 1, wherein
wherein the electron transport layer comprises a zinc oxide nanoparticle, and optionally, the zinc oxide nanoparticle comprises an alkali metal, an alkaline earth metal, Zr, W, Li, Ti, Y, Al, Ga, In, Sn, Co, V, or a combination thereof.

4. The electroluminescent device of claim 1, wherein
the zinc oxide nanoparticle has a particle size of greater than or equal to about 1 nanometer and less than or equal to about 10 nanometers.

5. The electroluminescent device of claim 1, wherein
the plurality of first semiconductor nanoparticles and the plurality of second semiconductor nanoparticles do not comprise cadmium, lead, or a combination thereof, and the plurality of the first semiconductor nanoparticles and the plurality of the second semiconductor nanoparticles comprise an indium phosphide, an indium zinc phosphide, a zinc chalcogenide, or a combination thereof.

6. The electroluminescent device of claim 1, wherein
the plurality of second semiconductor nanoparticles comprises an organic ligand coordinated on a surface of the plurality of second semiconductor nanoparticles, and optionally, a halogen bound to the surface, and
the organic ligand comprises RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, or a combination thereof, wherein R and R′ are each independently a substituted or unsubstituted C1 to C40 aliphatic hydrocarbon, or a substituted or unsubstituted C6 to C40 aromatic hydrocarbon, or a combination thereof.

7. The electroluminescent device of claim 1, wherein
a population density of the plurality of first semiconductor nanoparticles in the first layer is less than a population density of the plurality of second semiconductor nanoparticles in the second layer.

8. The electroluminescent device of claim 1, wherein
the second layer does not comprise a phenyl phosphoryl benzene compound, a diphenyl phosphinylphenyl triazine compound, or a combination thereof.

9. The electroluminescent device of claim 1, wherein the multi-layered light emitting film is configured to exhibit a residual thickness percentage of greater than or equal to about 10% and less than or equal to 100% with respect to a C5-18 aliphatic hydrocarbon solvent, the residual thickness percentage being defined by the following equation:
residual thickness percentage=[B/A]×100
A: initial thickness of the multi-layered light emitting film
B: a thickness of the multi-layered light emitting film after being in contact with a given solvent for greater than or equal to 5 and less than or equal to 60 seconds.

10. The electroluminescent device of claim 1, wherein the first layer is configured to exhibit a residual thickness percentage of greater than or equal to about 82% with respect to a C5-18 aliphatic hydrocarbon solvent, the residual thickness percentage being defined by the following equation:
residual thickness percentage=[B/A]×100
A: initial thickness of the first layer
B: a thickness of the first layer after being in contact with a given solvent for greater than or equal to 5 and less than or equal to 60 seconds.

11. The electroluminescent device of claim 1, wherein the p-type organic semiconductor polymer comprises a substituted or unsubstituted alkylene group, a substituted or unsubstituted phenylene group, a substituted or unsubstituted biphenylene group, —NR—, an ether group, or a combination thereof, wherein R is a substituted or unsubstituted C1-30 aliphatic hydrocarbon group, a substituted or unsubstituted C3-60 aromatic hydrocarbon group, a substituted or unsubstituted C3-30 heteroaromatic hydrocarbon group, a substituted or unsubstituted C3-30 alicyclic hydrocarbon group, a substituted or unsubstituted C3-30 heteroalicyclic hydrocarbon group, or a combination thereof, and
optionally the p-type organic semiconductor polymer has a molecular weight of greater than or equal to about 1000 g/mol and less than or equal to about 100,000 g/mol.

12. The electroluminescent device of claim 1, wherein the p-type organic semiconductor polymer has a LUMO energy level of less than 3 eV.

13. The electroluminescent device of claim 1, wherein
a thickness of the multi-layered light emitting film is greater than or equal to about 10 nanometers and less than or equal to about 100 nanometers; or a thickness of the first layer is greater than or equal to about 5 nanometers and less than or equal to about 60 nanometers, and a thickness of the second layer is greater than or equal to about 5 nanometers and less than or equal to about 60 nanometers.

14. The electroluminescent device of claim 1, wherein
the electroluminescent device is configured to exhibit a maximum external quantum efficiency of greater than or equal to about 10% and
the electroluminescent device is configured to exhibit a maximum luminance of 75,000 candela per square meter.

15. The electroluminescent device of claim 1, wherein
the electroluminescent device is configured to exhibit a T90 of greater than or equal to about 15 hours with an initial luminance of about 650 nit, or
the electroluminescent device is configured to exhibit a voltage increase of less than or equal to about 0.6 volts with a luminance of about 650 nit for about 80 hours.

16. The electroluminescent device of claim 1, wherein in the electroluminescent device,
the second layer is disposed between the first layer and the electron transport layer; or
the first layer is disposed between the second layer and the electron transport layer.

17. A method of manufacturing the electroluminescent device of claim 1, which comprises:
providing a first electrode, forming a multi-layered light emitting film on the first electrode, forming an electron transport layer on the multi-layered light emitting film, and providing a second electrode on the electron transport layer,
wherein the forming of the multilayer light emitting layer comprises:
forming a film comprising a first composition comprising an organic solvent, a precursor of a p-type organic semiconductor polymer, and first semiconductor nanoparticles, and thermally treating the film at a temperature of greater than or equal to about 110° C. and less than or equal to about 180° C. to form a first layer;
and forming a film of a second composition including an organic solvent and the second semiconductor nanoparticles and removing the organic solvent from the film to form a second layer.

18. The method of claim 17, wherein the formation of the first layer does not involves UV light irradiation.

19. A display device comprising the electroluminescent device of claim 1.

20. The display device of claim 19, wherein
the display device comprises a portable terminal device, a monitor, a notebook computer, a television, an electric sign board, a camera, or an electronic component.
